(19) United States
(12) Patent Application Publication
(10) Pub. No.: US 2026/0181881 A1
(43) Pub. Date: Jun. 25, 2026

(54) SEMICONDUCTOR DEVICE HAVING THROUGH VIA AND METHOD FOR MANUFACTURING OF SEMICONDUCTOR DEVICE

(71) Applicant: Samsung Electronics Co., Ltd., Suwon-si (KR)

(72) Inventors: Chanmi LEE, Suwon-si (KR); Jae-Wha PARK, Suwon-si (KR); Kwangjin MOON, Suwon-si (KR); Eunmi KIM, Suwon-si (KR); Pil-Kyu KANG, Suwon-si (KR)

(21) Appl. No.: 19/424,449

(22) Filed: Dec. 18, 2025

(30) Foreign Application Priority Data
Dec. 23, 2024 (KR) 10-2024-0194427

(51) Int. Cl. H10B 12/00; H10B 80/00; H10W 90/00; H10W 90/20

(52) U.S. Cl. CPC H10B 12/50; H10B 12/33; H10B 80/00; H10W 90/291; H10W 90/297; H10W 90/792; H10W 90/794

(57) ABSTRACT

A semiconductor device comprises a semiconductor chip including a cell area including a memory cell, a peripheral circuit area stacked on the cell area in a first direction and including a peripheral circuit element electrically connected to the memory cell, a through via penetrating the cell area and the peripheral circuit area, a backside pad disposed below the cell area and electrically connected to the through via, and a frontside pad disposed above the peripheral circuit area and electrically connected to the through via. The cell area comprises a cell insulation layer surrounding the memory cell and a cell substrate disposed below the cell insulation layer. The peripheral circuit area comprises a peripheral circuit insulation layer surrounding the peripheral circuit element and a peripheral circuit substrate disposed below the peripheral circuit insulation layer, so the peripheral circuit substrate is between the peripheral circuit insulation layer and the cell insulation layer.

### CROSS-REFERENCE TO RELATED APPLICATIONS

This application claims the benefit of Korean Patent Application No. 10-2024-0194427, filed on Dec. 23, 2024, in the Korean Intellectual Property Office, the disclosure of which is incorporated herein by reference in its entirety.

### BACKGROUND

### 1. Field of the Invention

Example embodiments relate to a semiconductor chip, a semiconductor package and a method for manufacturing of the semiconductor chip.

### 2. Description of the Related Art

With the development of the electronic industry, the demand for high functionality, high speed, and miniaturization for electronic components is increasing. In response to this trend, a method of stacking and mounting various semiconductor chips in a package wiring structure or stacking one package on the top of another may be used. For example, a package-in-package (PIP) semiconductor package or a package-on-package (POP) semiconductor package may be used.

Meanwhile, as semiconductor packages have become highly integrated, a vertical wiring structure that vertically stacks and electrically connects semiconductor chips has become increasingly used.

### SUMMARY

An aspect provides a semiconductor chip having improved capacity and a manufacturing method thereof.

Another aspect provides a semiconductor package with a decreased risk of warpage.

Technical goals of the present disclosure are not limited to the aforementioned technical goals, and other unstated technical goals may be clearly understood by those who skilled in the art from example embodiments below.

According to an aspect, A semiconductor device comprises a semiconductor chip including a cell area including a memory cell, a peripheral circuit area stacked on the cell area in a first direction and including a peripheral circuit element electrically connected to the memory cell, a through via penetrating the cell area and the peripheral circuit area in the first direction, a backside pad disposed below the cell area and electrically connected to the through via, and a frontside pad disposed above the peripheral circuit area and electrically connected to the through via. The cell area comprises a cell insulation layer surrounding the memory cell and a cell substrate disposed below the cell insulation layer. The peripheral circuit area comprises a peripheral circuit insulation layer surrounding the peripheral circuit element and a peripheral circuit substrate disposed below the peripheral circuit insulation layer, so that the peripheral circuit substrate is between the peripheral circuit insulation layer and the cell insulation layer. The through via penetrates the cell substrate, the cell insulation layer, the peripheral circuit substrate, and the peripheral circuit insulation layer along the first direction.

According to another aspect, A semiconductor device comprises a package substrate, a first semiconductor chip on the package substrate, and a second semiconductor chip bonded to the first semiconductor chip and disposed on the first semiconductor chip in a first direction. The first semiconductor chip comprises a first cell area including a memory cell, a first peripheral circuit area that includes a peripheral circuit element and is arranged with the first cell area in the first direction. a first through via penetrating the first cell area and the first peripheral circuit area, a first backside pad that faces the first cell area so that the first cell area is at a vertical level between the first backside pad and the first peripheral circuit area, and is connected to the first through via, and a first frontside pad that faces the first peripheral circuit area so that the first peripheral circuit area is at a vertical level between the first frontside pad and the first cell area, and is electrically connected to the first through via. The second semiconductor chip comprises a second cell area including a memory cell, a second peripheral circuit area that includes a peripheral circuit element and is arranged with the second cell area in the first direction, a second through via penetrating the second cell area and the second peripheral circuit area, a second backside pad that faces the second cell area so that the second cell area is at a vertical level between the second backside pad and the second peripheral circuit area, and is connected to the second through via, and a second frontside pad that faces the second peripheral circuit area so that the second peripheral circuit area is at a vertical level between the second frontside pad and the second cell area, and is electrically connected to the second through via. The first frontside pad and the second frontside pad are bonded to each other, the first cell area comprises a first cell substrate and a first cell insulation layer, and the first peripheral circuit area comprises a first peripheral circuit substrate and a first peripheral circuit insulation layer. The first through via penetrates the first cell substrate, the first cell insulation layer, the first peripheral circuit substrate and the first peripheral circuit insulation layer along the first direction, the second cell area comprises a second cell substrate and a second cell insulation layer, the second peripheral circuit area comprises a second peripheral circuit substrate and a second peripheral circuit insulation layer, and the second through via penetrates the second cell substrate, the second cell insulation layer, the second peripheral circuit substrate, and the second peripheral circuit insulation layer along the first direction.

According to another aspect, A semiconductor device comprises a first semiconductor chip, a second semiconductor chip bonded to the first semiconductor chip and disposed on the first semiconductor chip in a first direction, and a third semiconductor chip bonded the second semiconductor chip and disposed on the second semiconductor chip in the first direction. The first semiconductor chip comprises a first cell area including a vertical channel transistor, a first peripheral circuit area that includes a peripheral circuit element electrically connected to the vertical channel transistor of the first cell area and is arranged with the first cell area in the first direction, and a first through via penetrating the first cell area and the first peripheral circuit area. The second semiconductor chip comprises a second cell area comprising a vertical channel transistor, a second peripheral circuit area that includes a peripheral circuit element electrically connected to the vertical channel transistor of the second cell area and is arranged with the second cell area in the first direction, and a second through via penetrating the second cell area and the second peripheral circuit area. The third semiconductor chip comprises a third cell area including a vertical channel transistor, a third peripheral circuit area that includes a peripheral circuit element electrically connected to the vertical channel transistor of the third cell area and is arranged with the third cell area in the first direction, and a third through via penetrating the third cell area and the third peripheral circuit area. In the first direction, a top of the first peripheral circuit area faces a bottom of the second peripheral circuit area, and a top of the second cell area faces a bottom of the third cell area.

According to another aspect, a method for manufacturing of the semiconductor chip includes forming a memory cell and a cell insulation layer covering the memory cell on a cell substrate, forming a peripheral circuit element and a peripheral circuit insulation layer covering the peripheral circuit element on a peripheral circuit substrate, disposing the peripheral circuit substrate on the cell substrate and bonding the peripheral circuit substrate to the cell substrate, forming a through via penetrating the cell substrate and the peripheral circuit substrate, forming a chip wiring structure electrically connected to the through via and the peripheral circuit element on the through via and the peripheral circuit element, forming a frontside pad electrically connected to the chip wiring structure on the chip wiring structure, and forming a backside pad connected to the through via below the cell substrate and the through via.

According to another aspect, the through via includes a first portion penetrating the cell substrate and the cell insulation layer and a second portion penetrating the peripheral circuit substrate and the peripheral circuit insulation layer, and forming the through via comprises before bonding the peripheral circuit substrate on the cell substrate, forming the first portion penetrating the cell substrate and the cell insulation layer, before bonding the peripheral circuit substrate on the cell substrate, forming the second portion penetrating the peripheral circuit substrate and the peripheral circuit insulation layer and connecting the first portion and the second portion.

According to another aspect, the through via includes a first portion penetrating the cell substrate and the cell insulation layer and a second portion penetrating the peripheral circuit substrate and the peripheral circuit insulation layer, and forming the through via comprises before bonding the peripheral circuit substrate on the cell substrate, forming the first portion penetrating the cell substrate and the cell insulation layer, after bonding the peripheral circuit substrate on the cell substrate, forming a trench of the second portion penetrating the peripheral circuit substrate and the peripheral circuit insulation layer and exposing at least a part of the first portion and forming the second portion within the trench of the second portion.

According to another aspect, bonding the peripheral circuit substrate on the cell substrate comprises bonding the cell insulation layer and the peripheral circuit substrate.

According to another aspect, forming the through via comprises after bonding the peripheral circuit substrate on the cell substrate, forming a through via trench penetrating the cell substrate, the cell insulation layer, the peripheral circuit substrate, and the peripheral circuit insulation layer and forming a through via insulation layer surrounding the through via and the through via within the through via trench.

Details of example embodiments are included in the detailed description and drawings.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a schematic diagram illustrating a cross section of a semiconductor chip according to some example embodiments;

FIG. 2A is an exemplary enlarged view illustrating part P of FIG. 1;

FIG. 2B is an exemplary enlarged view illustrating part Q of FIG. 2A;

FIG. 3 is an exemplary enlarged view illustrating part P of FIG. 1 to explain a semiconductor chip according to other some example embodiments;

FIG. 4 is an exemplary enlarged view illustrating part P of FIG. 1 to explain a semiconductor chip according to other some example embodiments;

FIG. 5 is an exemplary enlarged view illustrating part P of FIG. 1 to explain a semiconductor chip according to other some example embodiments;

FIG. 6 is an exemplary enlarged view illustrating part P of FIG. 1 to explain a semiconductor chip according to other some example embodiments;

FIG. 7 is an exemplary enlarged view illustrating part P of FIG. 1 to explain a semiconductor chip according to other some example embodiments;

FIG. 8 is an exemplary enlarged view illustrating part P of FIG. 1 to explain a semiconductor chip according to other some example embodiments;

FIG. 9 is an exemplary enlarged view illustrating part P of FIG. 1 to explain a semiconductor chip according to other some example embodiments;

FIG. 10 is a schematic diagram illustrating a cross section of a semiconductor package according to some example embodiments;

FIGS. 11 to 15 are exemplary diagrams illustrating an intermediate operation to explain a method for manufacturing of the semiconductor chip shown in FIG. 2; and

FIGS. 16 to 22 are exemplary diagrams illustrating an intermediate operation to explain a method for manufacturing of the semiconductor chip shown in FIG. 5.

### DETAILED DESCRIPTION

The example embodiments described in this specification and the configurations shown in the drawings represent mere example embodiments of the present disclosure and do not encompass the entire technical idea of the present disclosure. Therefore, at the point of the present application, the possibility of various equivalents and modified examples that may serve as replacements should be understood.

In the description below, items described in the singular may apply to items shown to be provided in plural, unless clearly indicated otherwise in context. Terms such as “comprise or include” should be understood as indicating the existence of a feature, number, step, operation, element, component, or combination thereof described in this specification, and the terms do not exclude in advance the existence or the possibility of one or more additional features, numbers, steps, operations, elements, components, or combinations thereof. Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

In addition, terms such as “first” and “second” may be used to describe various components, but the components are not limited by the terms, and the terms may simply be used to distinguish one component from another. Within the scope of the technical ideas of the present disclosure, a first component may be designated as a second component, and similarly, a second component may be designated as a first component, either in the specification or the claims. Furthermore, in the drawings, a form or a size of components may be exaggerated to emphasize clarity in the description.

In addition, in the description below, expressions such as above, upper portion, below, lower portion, side surface, frontside, backside are expressed based on a direction shown in a drawing, and when the orientation changes, the expressions may be expressed differently.

An item, layer, or portion of an item or layer described as extending “lengthwise” in a particular direction has a length in the particular direction and a width perpendicular to that direction, where the length is greater than the width.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Items described as “connected” may be physically and/or electrically connected.

Hereinafter, example embodiments according to the present disclosure are described with reference to the accompanying drawings.

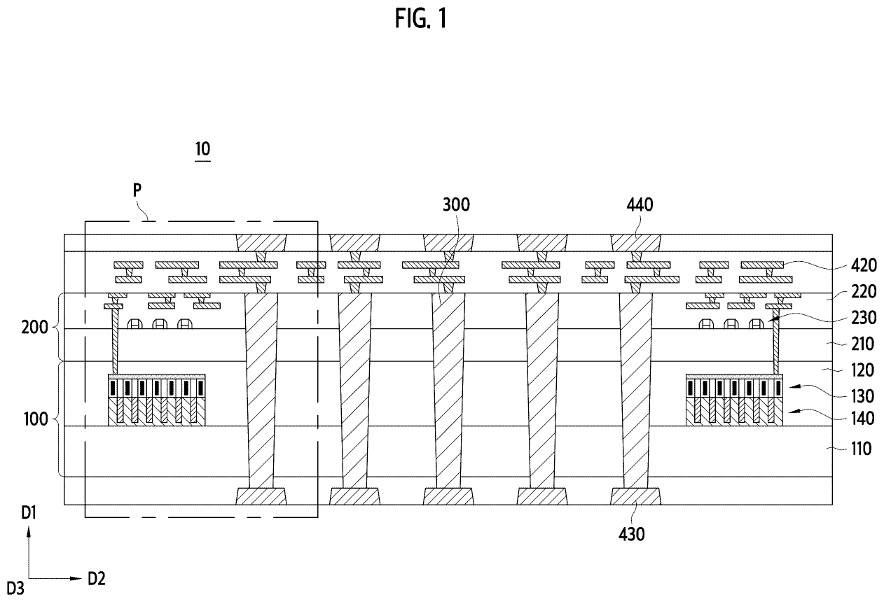

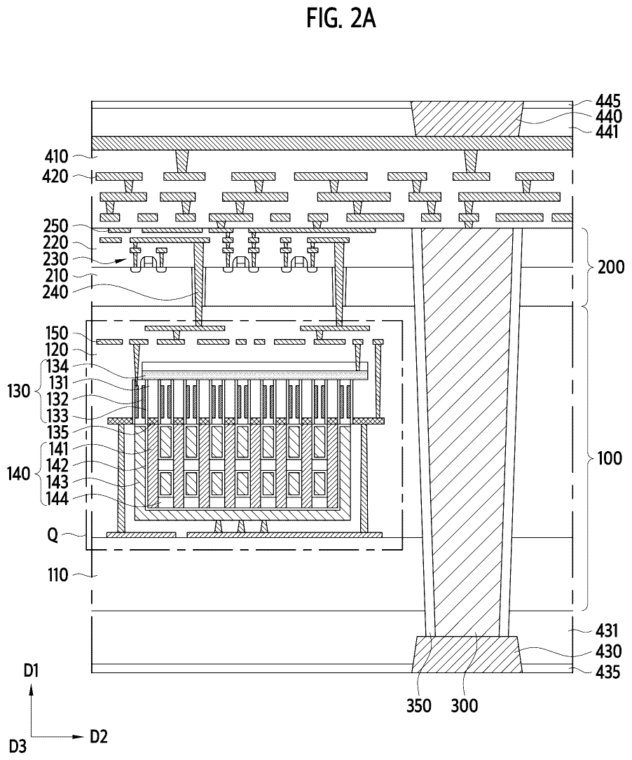

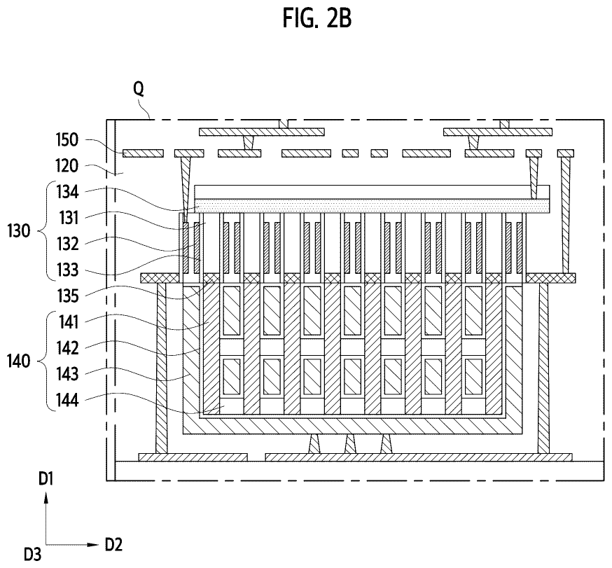

FIG. 1 is a schematic diagram illustrating a cross section of a semiconductor chip according to some example embodiments. FIG. 2A is an exemplary enlarged view illustrating part P of FIG. 1. FIG. 2B is an exemplary enlarged view illustrating part Q of FIG. 2A.

Referring to FIGS. 1, 2A, and 2B, a semiconductor chip 10 according to some example embodiments may include a cell area 100, a peripheral circuit area 200, a through via 300, a chip wiring structure 420, a backside pad 430 and a frontside pad 440.

According to some example embodiments, the semiconductor chip 10 may be an integrated circuit (IC) where hundreds to millions of semiconductor devices or more are integrated in one chip. For example, the semiconductor chip 10 may be a volatile memory chip such as dynamic random access memory (DRAM) or static random access memory (SRAM). Alternatively, the semiconductor chip 10 may be a nonvolatile memory chip such as flash memory, phase-change RAM (PRAM), magnetoresistive RAM (MRAM), ferroelectricRAM (FeRAM), or resistive RAM (RRAM). As another example, the semiconductor chip 10 may be a logic chip. The semiconductor chip 10 may be an application processor (AP) such as a central processing unit (CPU), a graphic processing unit (GPU), a field-programmable gate array (FPGA), a digital signal processor, a cryptography processor, a microprocessor, or a microcontroller, but is not limited thereto.

According to some example embodiments, the cell area 100 may include a variety of multiple semiconductor elements. The cell area 100 may include various microelectronic devices, for example, metal-oxide-semiconductor field effect transistor (MOSFET) such as complementary metal-oxide-semiconductor (CMOS) transistor, system large scale integration (LSI), flash memory, DRAM, SRAM, electrically erasable programmable read-only memory (EEPROM), PRAM, MRAM, RRAM, an image sensor such as a CMOS imaging sensor (CIS), a micro-electro-mechanical system (MEMS), an active element, and a passive element.

According to some example embodiments, the cell area 100 may include a cell substrate 110, a cell insulation layer 120, memory cells (combined 130 and 140), and a cell wiring 150.

According to some example embodiments, the cell substrate 110 may be, for example, bulk silicon or silicon-on-insulator (SOI). As another example, the cell substrate 110 may be a silicon substrate. As another example, the cell substrate 110 may include silicon germanium, silicon germanium on insulator (SGOI), indium antimonide, lead telluride, indium arsenide, indium phosphide, gallium arsenide, or gallium antimonide, but is not limited thereto.

According to some example embodiments, the cell substrate 110 may include a conductive region, for example, an impurity-doped well or an impurity-doped structure. The cell substrate 110 may have various element isolation structures such as a shallow trench isolation (STI) structure.

According to some example embodiments, the cell insulation layer 120 may be disposed on the cell substrate 110 in a first direction D1. The first direction D1 may indicate a direction in which the cell substrate 110 and the cell insulation layer 120 are arranged. For example, the first direction D1 may indicate a direction that crosses an upper surface or a lower surface of the cell substrate 110, and may be a vertical direction perpendicular to a top surface of the cell substrate 110. The cell substrate 110 and the cell insulation layer 120 may be arranged with respect to each other in the first direction D1. The cell insulation layer 120 may be disposed between the cell substrate 110 and a peripheral circuit substrate 210 in the first direction D1. The cell insulation layer 120 may surround the memory cells (combined 130 and 140). The cell insulation layer 120 may cover the memory cells (combined 130 and 140).

According to some example embodiments, the cell insulation layer 120 may include at least one of silicon oxide, silicon nitride, silicon oxynitride (SiON), silicon oxycarbonitride (SiOCN), tetra ethyl ortho silicate (TEOS) and a combination thereof. The cell insulation layer 120 may include a different material from that of the cell substrate 110.

According to some example embodiments, the memory cells 130 and 140 may be disposed in the cell area 100. The memory cells (combined 130 and 140) may be disposed above the cell substrate 110. The memory cells 130 and 140 may be disposed within the cell insulation layer 120. For example, the memory cells (combined 130 and 140) may be DRAM cells. The memory cells (combined 130 and 140) may each include a vertical channel transistor 130 and a capacitor 140. The memory cells may be arranged in an array pattern to form a memory cell array.

According to some example embodiments, each vertical channel transistor (VCT) 130 may include a channel layer 131, a gate electrode 132, a gate insulation layer 133 and a bit line 134. A plurality of channel layers 131 may be connected to bit line 134.

According to some example embodiments, the channel layer 131 may extend in the first direction D1. The channel layer 131 may extend lengthwise in the first direction D1 that crosses the cell substrate 110. The VCT, for example, may indicate a structure for which a channel length of the channel layer 131 extends along a vertical direction from the cell substrate 110. For example, the channel layer 131 may extend lengthwise in the vertical direction (e.g., first direction D1).

According to some example embodiments, the channel layer 131 may be one of a plurality of channel layers 131 arranged in a matrix form to be spaced apart in a second direction D2 and a third direction D3 at a vertical height below the bit line 134. The second direction D2 and the third direction D3 may cross the first direction D1. The second direction D2 and the third direction D3 may cross each other. The second direction D2 and the third direction D3 may designate a direction that is parallel to the upper surface or the lower surface of the cell substrate 110. The second direction D2 and the third direction D3 may be horizontal directions perpendicular to each other and perpendicular to the vertical direction. Each channel layer 131 may have a first width along the second direction D2 and a height along the first direction D1, and the height may be greater than the width. For example, the height of the channel layer 131 may be about twice to ten times greater than the width of the channel layer 131, but is not limited thereto. Each channel layer 131 may also have a second width along a third direction D3. A bottom portion of the channel layer 131 may function as a first source/drain area, and an upper portion of the channel layer 131 may function as a second source/drain area, and a part of the channel layer 131 between first and the second source/drain areas may function as a channel area (not illustrated).

According to some example embodiments, the channel layer 131 may include an oxide semiconductor, and for example, the oxide semiconductor may include indium gallium zinc oxide (InxGayZnzO), indium gallium silicon oxide (InxGaySizO), indium tin zinc oxide (InxSnyZnzO), indium zinc oxide (InxZnyO), zinc oxide (ZnxO), zinc tin oxide (ZnxSnyO), zinc oxynitride (ZnxOyN), zirconium tin zinc oxide (ZrxZnySnzO), tin oxide (SnxO), hafnium indium zinc oxide (HfxInyZnzO), gallium zinc tin oxide (GaxZnySnzO), aluminum zinc tin oxide (AlxZnySnzO), yttrium gallium zinc oxide (YbxGayZnzO), indium gallium oxide (InxGayO), or a combination thereof. The channel layer 131 may include a single layer or a multi-layer of the oxide semiconductor. In some example embodiments, the channel layer 131 may have a bandgap energy that is greater than a bandgap energy of silicon. For example, the channel layer 131 may have a bandgap energy of about 1.5 electron volt (eV) to 5.6 eV. For example, the channel layer 131 may have optimal channel performance with a bandgap energy of about 2.0 eV to 4.0 eV. For example, the channel layer 131 may be polycrystalline or non-crystalline, but is not limited thereto. In some example embodiments, the channel layer 131 may include a two-dimensional (2D) semiconductor material, and for example, the 2D semiconductor material may include graphene, carbon nanotube, or a combination thereof.

According to some example embodiments, the gate electrode 132 may extend on both side surfaces of the channel layer 131 in the first direction D1 and the third direction D3. The gate electrode 132 may include two gate electrodes 132 (e.g., two gate sub-electrodes) facing opposite side surfaces of the channel layer 131 arranged in the second direction D2. Each gate electrode 132 may extend lengthwise in the third direction D3. As one channel layer 131 is disposed between the two gate electrodes 132, a semiconductor device may have a dual-gate transistor structure. However, the present disclosure is not limited thereto, and a single gate transistor structure may also be embodied when one of the two gate electrodes 132 is omitted, and a single gate electrode 132 facing one side surface of the channel layer 131 is formed.

According to some example embodiments, the gate electrode 132 may include doped polysilicon, a metal, conductive metal nitride, conductive metal silicide, conductive metal oxide, or a combination thereof. For example, the gate electrode 132 may be composed of doped polysilicon, aluminum (Al), copper (Cu), titanium (Ti), tantalum (Ta), ruthenium (Ru), tungsten (W), molybdenum (Mo), platinum (Pt), nickel (Ni), cobalt (Co), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicide (TaSi), tantalum silicide nitride (TaSiN), ruthenium titanium nitride (RuTiN), nickel silicide (NiSi), cobalt silicide (CoSi), iridium oxide (IrOx), ruthenium oxide (RuOx), or a combination thereof, but is not limited thereto.

According to some example embodiments, the gate insulation layer 133 may surround a side surface of the channel layer 131 and be interposed between the channel layer 131 and the gate electrode 132. For example, an entire side surface of the channel layer 131 may be surrounded by the gate insulation layer 133 (e.g., when viewed from a top-down view and where the channel layer 131 has a circular or polygon shape), and a part of a side surface of the gate electrode 132 may be in contact with the gate insulation layer 133. In other example embodiments, the gate insulation layer 133 may extend in an extending direction (namely, the first direction D1 and the third direction D3) of the gate electrode 132, and among side surfaces of the channel layer 131, only two side surfaces facing the gate electrode 132 may be in contact with the gate insulation layer 133.

According to some example embodiments, the gate insulation layer 133 may be composed of a silicon oxide layer, a silicon oxynitride layer, a high-k dielectric layer with a higher dielectric constant than a silicon oxide layer, or a combination thereof. The high-k dielectric layer may be composed of metal oxide or metal oxynitride. For example, a high-k dielectric layer that may be used as the gate insulation layer 133 may be composed of hafnium dioxide (HfO2), hafnium silicate (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO2), aluminum oxide (Al2O3), or a combination thereof, but is not limited thereto.

According to some example embodiments, the bit line 134 may be disposed above the channel layer 131 and the gate electrode 132 in the first direction D1. The bit line 134 may extend (e.g., lengthwise) in the second direction D2.

According to some example embodiments, the bit line 134 may include doped polysilicon, a metal, conductive metal nitride, conductive metal silicide, conductive metal oxide, or a combination thereof. For example, the bit line 134 may be composed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto. The bit line 134 may include a single layer or a multi-layer of the aforementioned materials. In some example embodiments, the bit line 134 may include a 2D semiconductor material, and for example, the 2D semiconductor material may include graphene, carbon nanotube, or a combination thereof.

According to some example embodiments, a connection pad 135 may be disposed between the VCT 130 and the capacitor 140. The connection pad 135 may connect the vertical channel transistor 130 and the capacitor 140. The connection pad 135 may overlap with the channel layer 131 of the vertical channel transistor 130 and a first electrode 141 of the capacitor 140 in the first direction D1. The connection pad 135 may be composed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

According to some example embodiments, the capacitor 140 may be connected to the vertical channel transistor 130. The capacitor 140 may be arranged with the vertical channel transistor 130 in the first direction D1. The capacitor 140 may include the first electrode 141, a dielectric layer 142, a second electrode 143, and a support structure 144.

According to some example embodiments, the first electrode 141 may be disposed above the cell substrate 110. The first electrode 141 may be disposed under the connection pad 135. The first electrode 141 may be connected to the connection pad 135. Each first electrode 141 may have a pillar shape. The first electrode 141 may be extended longitudinally in a thickness direction of the cell substrate 110. A length of the first electrode 141 extending in the first direction D1 is greater than a length of the first electrode 141 extending in the second direction D2 parallel to the cell substrate 110.

According to some example embodiments, a group of first electrodes 141 may be repetitively arranged along the second direction D2 and the third direction D3. The first electrodes 141 repetitively arranged in the second direction D2 may not be arranged straight along the second direction D2. The first electrodes 141 repetitively arranged in the second direction D2 may be arranged in zigzags.

According to some example embodiments, the first electrode 141, for example, may include a doped semiconductor material, conductive metal nitride (for example, titanium nitride, tantalum nitride, niobium nitride, or tungsten nitride), a metal (for example, ruthenium, iridium, titanium, or tantalum), and conductive metal oxide (for example, iridium oxide, or niobium oxide), and the like, but is not limited thereto.

According to some example embodiments, the dielectric layer 142 may be formed on the first electrode 141 and the support structure 144. The dielectric layer 142 may extend along surfaces of the first electrode 141 and the support structure 144.

According to some example embodiments, the dielectric layer 142, for example, may include a high permittivity material including silicon oxide, silicon nitride, silicon oxynitride, and a metal. The dielectric layer 142 is illustrated as a single layer, merely for the convenience of explanation, but is not limited thereto.

According to some example embodiments, the dielectric layer 142 may include a stacked layer structure where zirconium oxide, aluminum oxide, and zirconium oxide are sequentially stacked.

According to some example embodiments, the dielectric layer 142 may be a dielectric layer including hafnium (Hf). The dielectric layer 142 may have a stacked layer structure of a ferroelectric material layer and a paraelectric material layer.

According to some example embodiments, the ferroelectric material layer may have a ferroelectric characteristic. The ferroelectric material layer may have a thickness for having the ferroelectric characteristic. A range of the thickness of the ferroelectric material layer having the ferroelectric characteristic may vary depending on a ferroelectric material.

For example, the ferroelectric material layer may include monometal oxide. The ferroelectric material layer may include a monometal oxide layer. Here, monometal oxide may be a binary compound consisting of one metal and oxygen. The ferroelectric material layer including monometal oxide may have an orthorhombic crystal system.

As an example, a metal that is included in a monometal oxide layer may be hafnium (Hf). The monometal oxide layer may be a hafnium oxide layer (HfO). Here, the hafnium oxide layer may have a chemical formula corresponding to stoichiometry or have a chemical formula not corresponding to stoichiometry.

As another example, a metal that is included in the monometal oxide layer may be one of rare earth metals belonging to lanthanoids. The monometal oxide layer may be a rare earth metal oxide layer belonging to lanthanoids. Here, the rare earth metal oxide layer belonging to lanthanoids may have a chemical formula corresponding to stoichiometry or have a chemical formula not corresponding to stoichiometry. When a ferroelectric material layer includes the monometal oxide layer, the ferroelectric material layer may have, for example, a thickness of greater than or equal to 1 nanometer (nm) and equal to or less than 10 nm.

For example, the ferroelectric material layer may include bimetal oxide. The ferroelectric material layer may include a bimetal oxide layer. Here, bimetal oxide may be a ternary chemical compound consisting of two metals and oxygen. The ferroelectric material layer including bimetal oxide may have an orthorhombic crystal system.

According to some example embodiments, a metal included in the bimetal oxide layer may be, for example, hafnium (Hf) and zirconium (Zr). The bimetal oxide layer may be a hafnium zirconium oxide layer (HfₓZr₍₁₋ₓ₎O). In the bimetal oxide layer, x may be greater than or equal to 0.2 and equal to or less than 0.8. Here, the hafnium zirconium oxide layer (HfₓZr₍₁₋ₓ₎O) may have a chemical formula corresponding to stoichiometry or have a chemical formula not corresponding to stoichiometry. When the ferroelectric material layer includes the bimetal oxide layer, the ferroelectric material layer may have, for example, a thickness of greater than or equal to 1 nm and equal to or less than 20 nm.

For example, the paraelectric material layer may be a dielectric layer including zirconium (Zr) or a stacked layer including zirconium (Zr), but is not limited thereto. Even though a chemical formula is the same, a ferroelectric characteristic or a paraelectric characteristic may be exhibited depending on a crystal structure of a dielectric material.

According to some example embodiments, a paraelectric material may have a positive dielectric constant, and a ferroelectric material may have a negative dielectric constant in a predetermined interval. For example, the paraelectric material may have a positive capacitance and the ferroelectric material may have a negative capacitance.

Generally, when two or more capacitors with positive capacitances are connected in series, the sum of the capacitances decreases. However, a negative capacitor with a negative capacitance and a positive capacitor with a positive capacitance are connected in series, the sum of the capacitances increases.

According to some example embodiments, the second electrode 143 may be disposed on the dielectric layer 142. The second electrode 143 may be disposed between the two support structures 144 spaced apart in the first direction D1. The second electrode 143 may be disposed below the first electrode 141 and the support structure 144. The second electrode 143 may extend along a profile of the dielectric layer 142. The second electrode 143 may include, for example, a doped semiconductor material, conductive metal nitride (for example, titanium nitride, tantalum nitride, niobium nitride, or tungsten nitride), a metal (for example, ruthenium, iridium, titanium, or tantalum), conductive metal oxide (for example, iridium oxide, or niobium oxide), and the like, but is not limited thereto.

According to some example embodiments, a plurality of the support structures 144 may be disposed to be spaced apart in the first direction D1. The support structure 144 may overlap with the first electrode 141 in the second direction D2. The support structure 144 may be disposed between a plurality of the first electrodes 141 spaced apart in the second direction D2. The support structure 144 may support the first electrode 141.

According to some example embodiments, the support structure 144 may include an insulation material. For example, the support structure 144 may include at least one of silicon nitride, silicon carbonitride, silicon boron nitride, silicon carbon oxide, silicon oxynitride, silicon oxide, and silicon oxycarbonitride.

According to some example embodiments, the cell wiring 150 may be disposed in the cell area 100. The cell wiring 150 may be disposed within the cell insulation layer 120. The cell wiring 150 may be electrically connected to the vertical channel transistor 130 and the capacitor 140 in the cell area 100.

According to some example embodiments, the cell wiring 150 may include a metal wiring layer and a via plug. For example, the cell wiring 150 may be a multi-layer structure where two or more metal wiring layers or two or more via plugs are alternately stacked. The cell wiring 150 may include a conductive material. For example, the cell wiring 150 may include copper (Cu), aluminum (Al), silver (Ag), tin (Sn), gold (Au), nickel (Ni), lead (Pb), titanium (Ti), or an alloy thereof, but is not limited thereto.

According to some example embodiments, the peripheral circuit area 200 may be disposed on the cell area 100. The peripheral circuit area 200 may be arranged with the cell area 100 in the first direction D1. The peripheral circuit area 200 may overlap with the cell area 100 in the first direction D1. The peripheral circuit area 200 may be bonded to the cell area 100 in the first direction D1. The peripheral circuit area 200 may include a peripheral circuit that controls an operation of the memory cells 130 and 140 of the cell area 100.

According to some example embodiments, the peripheral circuit area 200 may include the peripheral circuit substrate 210, a peripheral circuit insulation layer 220, a peripheral circuit element 230, a connecting via 240 and a peripheral circuit wiring 250.

According to some example embodiments, the peripheral circuit substrate 210 may be disposed above the cell substrate 110 and the cell insulation layer 120. The peripheral circuit substrate 210 may be bonded to the cell insulation layer 120, e.g., via direct insulator-to-insulator bonding. The peripheral circuit substrate 210 may be disposed between the cell insulation layer 120 and the peripheral circuit insulation layer 220 in the first direction D1.

According to some example embodiments, the peripheral circuit substrate 210 may be, for example, bulk silicon or silicon-on-insulator (SOI). As another example, the peripheral circuit substrate 210 may be a silicon substrate. As another example, the peripheral circuit substrate 210 may include silicon germanium, silicon germanium on insulator (SGOI), indium antimonide, lead telluride, indium arsenide, indium phosphide, gallium arsenide, or gallium antimonide, but is not limited thereto.

According to some example embodiments, the peripheral circuit substrate 210 may include a conductive area, for example, an impurity-doped well or an impurity-doped structure. The peripheral circuit substrate 210 may have various element isolation structures such as an STI structure.

According to some example embodiments, the peripheral circuit insulation layer 220 may be disposed on the peripheral circuit substrate 210 in the first direction D1. The peripheral circuit substrate 210 and the peripheral circuit insulation layer 220 may be arranged with each other in the first direction D1. The peripheral circuit insulation layer 220 may be disposed between the peripheral circuit substrate 210 and an interlayer insulation layer 410 in the first direction D1. The peripheral circuit insulation layer 220 may surround the peripheral circuit element 230. The peripheral insulation layer 220 may cover the peripheral circuit element 230.

According to some example embodiments, the peripheral circuit insulation layer 220 may include at least one of silicon oxide, silicon nitride, silicon oxynitride (SiON), silicon oxycarbonitride (SiOCN), TEOS and a combination thereof.

According to some example embodiments, the semiconductor chip 10 may have a cell on peri (COP) structure where the cell area 100 and the peripheral circuit area 200 are vertically stacked. By the cell area 100 and the peripheral circuit area 200 being vertically stacked, a capacity of the semiconductor chip 10 may be improved. According to example embodiments of the present disclosure, it is possible to improve a capacity of a semiconductor chip. The cell substrate 110, the cell insulation layer 120, the peripheral circuit substrate 210 and the peripheral circuit insulation layer 220 may be sequentially stacked in the first direction D1. The cell substrate 110 and the peripheral circuit substrate 210 may include a different material or material composition from a material or material composition that the cell insulation layer 120 and the peripheral circuit insulation layer 220 may include. The cell insulation layer 120 and the peripheral circuit insulation layer 220 may include a different material or material composition from a material or material composition that the cell substrate 110 and the peripheral circuit substrate 210 may include. For example, the cell insulation layer 120 and the peripheral circuit insulation layer 220 may include silicon oxide and not include bulk silicon, and the cell substrate 110 and the peripheral circuit substrate 210 may include bulk silicon.

According to some example embodiments, the peripheral circuit element 230 may be disposed on the peripheral circuit substrate 210. The peripheral circuit element 230 may be disposed within the peripheral circuit insulation layer 220. The peripheral circuit element 230 may be connected to the memory cells 130 and 140 through the connecting via 240. For example, the peripheral circuit element 230 may configure a variety of circuits such as a command decoder, a control logic, an address buffer, a row decoder, a column decoder, a sense amplifier, a sub-word line driver, or a data input/output circuit, but is not limited thereto.

According to some example embodiments, the connecting via 240 may connect (e.g., electrically connect) the cell area 100 and the peripheral circuit area 200. For example, the connecting via 240 may connect the peripheral circuit wiring 250 of the peripheral circuit area 200 and the cell wiring 150 of the cell area 100. The connecting via 240 may extend in the first direction D1. The connecting via 240 may penetrate the peripheral circuit substrate 210. The connecting via 240 may include a conductive material. For example, the connecting via 240 may include copper (Cu), aluminum (Al), silver (Ag), tin (Sn), gold (Au), nickel (Ni), lead (Pb), titanium (Ti), or an alloy thereof, but is not limited thereto.

According to some example embodiments, the peripheral circuit wiring 250 may be disposed in the peripheral circuit area 200. The peripheral circuit wiring 250 may be disposed above the peripheral circuit substrate 210. The peripheral circuit wiring 250 may be disposed within the peripheral circuit insulation layer 220. The peripheral circuit wiring 250 may be electrically connected to the peripheral circuit element 230.

According to some example embodiments, the peripheral circuit wiring 250 may include a metal wiring layer and a via plug. For example, the peripheral circuit wiring 250 may be a multi-layer structure where more than two metal wiring layers or more than two via plugs are alternately stacked. The peripheral circuit wiring 250 may include a conductive material. For example, the peripheral circuit wiring 250 may include copper (Cu), aluminum (Al), silver (Ag), tin (Sn), gold (Au), nickel (Ni), lead (Pb), titanium (Ti), or an alloy thereof, but not be limited thereto.

According to some example embodiments, the through via 300 may penetrate at least a part of the semiconductor chip 10. The through via 300 may penetrate the cell area 100 and the peripheral circuit area 200. The through via 300 may penetrate the cell substrate 110, the cell insulation layer 120, the peripheral circuit substrate 210, and the peripheral circuit insulation layer 220. The through via 300 may extend in the first direction D1. The through via 300 may be electrically connected to the chip wiring structure 420. The through via 300 may be spaced apart from the memory cells 130 and 140, the cell wiring 150, the peripheral circuit element 230, and the peripheral circuit wiring 250 in the second direction D2. A plurality of the through vias 300 may be disposed to be spaced apart in the second direction D2 and the third direction D3.

According to some example embodiments, the width of the through via 300 in the second direction D2 may decrease along a direction from the peripheral circuit area 200 toward the cell area 100 (e.g., in a vertical direction from the peripheral circuit substrate 210 toward the cell substrate 110). As a distance from the backside pad 430 decreases, the width of the through via 300 in the second direction D2 may decrease. A cross section of the through via 300 may have a tapered shape.

According to some example embodiments, the through via 300 may be electrically connected to the backside pad 430 and the frontside pad 440. The through via 300 may contact (e.g., directly physically connect to) the backside pad 430. The through via 300 may be electrically connected to the frontside pad 440 through the chip wiring structure 420. As described herein, a frontside refers to an active surface of a semiconductor device or portion (e.g., an active surface of a cell area or peripheral circuit area at which active circuit elements such as transistors are formed), and a backside refers to the surface opposite the active surface (e.g., an inactive surface that does not include active circuit elements). A semiconductor device, as described herein, may refer to a semiconductor chip (e.g., an integrated circuit formed on a die from a wafer) such as a memory chip or logic chip, or may refer to a semiconductor package including a plurality of semiconductor chips formed on a package substrate, or to a portion of a semiconductor chip or semiconductor package.

In FIGS. 1 and 2, the through via 300 is illustrated as a single layer, example embodiments are not limited thereto. For example, the through via 300 may include a conductive multilayer.

According to some example embodiments, the through via 300 may include or be formed of a conductive material. For example, the through via 300 may include or be formed of a metal such as copper (Cu), aluminum (Al), silver (Ag), tin (Sn), gold (Au), nickel (Ni), lead (Pb), titanium (Ti), or an alloy thereof, but is not limited thereto.

In FIG. 1, in the semiconductor chip 10, the memory cells 130 and 140 and the peripheral circuit element 230 are illustrated as being disposed only outside of the through via 300 (e.g., outside of a region including the through via 300), but example embodiments are not limited thereto. For example, the memory cells 130 and 140 and the peripheral circuit element 230 may be disposed between two through vias 300 adjacent in the second direction D2 (e.g., within a region including a plurality of through vias 300 to be between at least two of the through vias 300).

According to some example embodiments, a via insulation layer 350 may surround the through via 300. The via insulation layer 350 may cover a side surface of the through via 300. The via insulation layer 350 may surround a side surface of the through via 300. The via insulation layer 350 may electrically insulate the through via 300 from the memory cells 130 and 140, the cell wiring 150, the peripheral circuit element 230, and the peripheral circuit wiring 250. The via insulation layer 350 may include at least one of silicon oxide, silicon nitride, silicon oxynitride (SiON), silicon oxycarbonitride (SiOCN), and a combination thereof.

According to some example embodiments, the chip wiring structure 420 may be disposed on the through via 300 and the peripheral circuit area 200. The chip wiring structure 420 may be electrically connected to the through via 300 and the peripheral circuit wiring 250. The chip wiring structure 420 may be disposed between the through via 300 and the frontside pad 440 in the first direction D1.

According to some example embodiments, the chip wiring structure 420 may include a metal wiring layer and a via plug. For example, the chip wiring structure 420 may be a multi-layer structure where two or more metal wiring layers or two or more via plugs are alternately stacked. The chip wiring structure 420 may include a conductive material. For example, the chip wiring structure 420 may include copper (Cu), aluminum (Al), silver (Ag), tin (Sn), gold (Au), nickel (Ni), lead (Pb), titanium (Ti), or an alloy thereof, but is not limited thereto.

According to some example embodiments, the chip wiring structure 420 may be disposed within the interlayer insulation layer 410. The interlayer insulation layer 410 may protect the chip wiring structure 420 from an external shock or humidity. The interlayer insulation layer 410 may include at least one of silicon oxide, silicon nitride, silicon oxynitride (SiON), silicon oxycarbonitride (SiOCN), TEOS, and a combination thereof.

According to some example embodiments, the backside pad 430 may be disposed below the cell area 100. The backside pad 430 may face the cell area 100 in the first direction D1. For example, from among the cell area 100 and the peripheral circuit area 200, the backside pad 430 may be closer vertically to the cell area 100. The backside pad 430 may be electrically connected to the through via 300. The backside pad 430 may penetrate at least a part of a backside passivation layer 431 and at least a part of a backside bonding layer 435. A bottom surface of the backside pad 430 may be exposed outside from the backside passivation layer 431 and the backside bonding layer 435. The backside passivation layer 431 and the backside bonding layer 435 may surround a side surface of the backside pad 430. The backside passivation layer 431 and the backside bonding layer 435 may be disposed below the cell area 100.

According to some example embodiments, the backside pad 430 may include at least one selected from aluminum (Al), copper (Cu), nickel (Ni), tungsten (W), platinum (Pt), and gold (Au), but is not limited thereto. The backside passivation layer 431 may be selected from an organic compound such as photosensitive polyimide (PSPI) and an inorganic compound such as silicon oxide, silicon nitride, and silicon oxynitride. The backside bonding layer 435 may include at least one of silicon oxide, silicon nitride, silicon oxynitride (SiON), silicon oxycarbonitride (SiOCN), and a combination thereof. The backside bonding layer 435 may include a non-conductive film (NCF), a non-conductive paste (NCP), an insulating polymer, or an epoxy resin, but is not limited thereto. The backside bonding layer 435 may be a tape that may mutually fix the semiconductor chip 10. The backside bonding layer 435 may be, for example, a tape including epoxy component. In some example embodiments, the backside bonding layer 435 may include silicon oxide. The backside bonding layer 435 may include a different material from a frontside bonding layer 445.

According to some example embodiments, the frontside pad 440 may be disposed above the peripheral circuit area 200. The frontside pad 440 may be disposed on the chip wiring structure 420. The frontside pad 440 may be electrically connected to the chip wiring structure 420. The frontside pad 440 may penetrate at least a part of a frontside passivation layer 441 and at least a part of the frontside bonding layer 445. A top surface of the frontside pad 440 may be exposed to the outside of the semiconductor chip 10 from the frontside passivation layer 441 and the frontside bonding layer 445. The frontside passivation layer 441 and the frontside bonding layer 445 may surround a side surface of the frontside pad 440. The frontside passivation layer 441 and the frontside bonding layer 445 may be disposed above the peripheral circuit area 200.

According to some example embodiments, the frontside pad 440 may include or be formed of at least one selected from aluminum (Al), copper (Cu), nickel (Ni), tungsten (W), platinum (Pt), and gold (Au), but is not limited thereto. The frontside passivation layer 441 may be selected from an organic compound such as PSPI and an inorganic compound such as silicon oxide, silicon nitride, and silicon oxynitride. The frontside bonding layer 445 may include or be formed of at least one of silicon oxide, silicon nitride, silicon oxynitride (SiON), silicon oxycarbonitride (SiOCN), and a combination thereof. The frontside bonding layer 445 may include or be an NCF, an NCP, an insulating polymer, or an epoxy resin, but is not limited thereto. The frontside bonding layer 445 may be a tape that may mutually fix the semiconductor chip 10. The frontside bonding layer 445 may be, for example, a tape including epoxy component. In some example embodiments, the frontside bonding layer 445 may include silicon carbonitride (SiCN). The frontside bonding layer 445 may include a different material from a material that the backside bonding layer 435 may include.

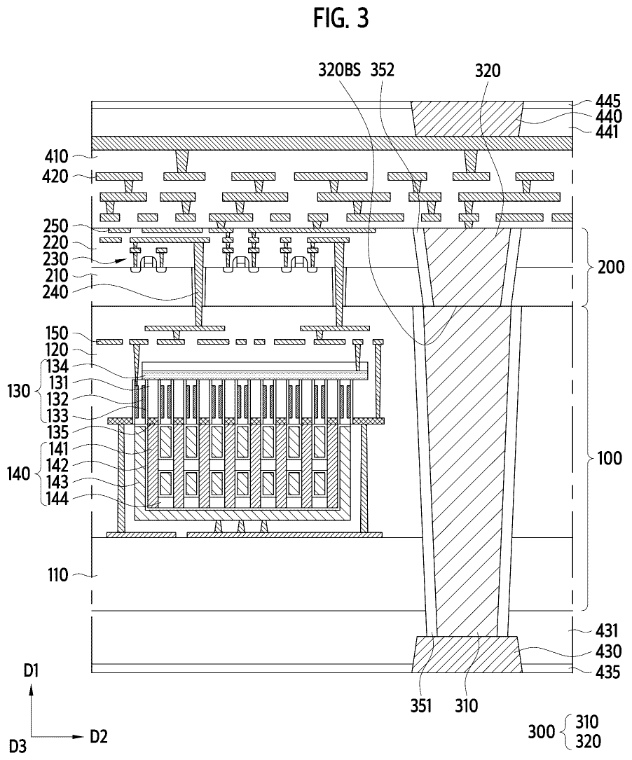

FIG. 3 is an exemplary enlarged view illustrating part P of FIG. 1 to explain a semiconductor chip according to other example embodiments. To explain a semiconductor chip according to other example embodiments, a difference from the description with reference to FIGS. 1 and 2 may be mainly described.

Referring to FIG. 3, the through via 300 may include a first portion 310 and a second portion 320. The first portion 310 and the second portion 320 may be connected in the first direction D1.

According to some example embodiments, the first portion 310 may be disposed between the backside pad 430 and the second portion 320 in the first direction D1. The first portion 310 may penetrate the cell area 100. The first portion 310 may penetrate the cell substrate 110 and the cell insulation layer 120. The first portion 310 may overlap with the cell substrate 110 and the cell insulation layer 120 in the second direction D2. The first portion 310 may overlap with the memory cells 130 and 140 and the cell wiring 150 in the second direction D2. As the distance from the peripheral circuit area 200 decreases, the width of the first portion 310 may increase in the second direction D2. As the distance from the backside pad 430 decreases, the width of the first portion 310 may decrease in the second direction D2.

According to some example embodiments, the second portion 320 may be disposed between the first portion 310 and the chip wiring structure 420 in the first direction D1. The second portion 320 may penetrate the peripheral circuit area 200. The second portion 320 may penetrate the peripheral circuit substrate 210 and the peripheral circuit insulation layer 220. The second portion 320 may overlap with the peripheral circuit substrate 210 and the peripheral circuit insulation layer 220 in the second direction D2. The second portion 320 may overlap with the peripheral circuit element 230 and the peripheral circuit wiring 250 in the second direction D2. As a distance from the cell area 100 decreases, the width of the second portion 320 may decrease in the second direction D2. As a distance from the chip wiring structure 420 decreases, the width of the second portion 320 may increase in the second direction D2.

According to some example embodiments, the through via 300 may have a step on a boundary surface of the cell area 100 and the peripheral circuit area 200. The first portion 310 and the second portion 320 may be connected with a step on a boundary surface of the cell area 100 and the peripheral circuit area 200. For example, a side surface of the first portion 310 and a side surface of the second portion 320 may not be connected on the same plane, but rather are disposed staggered. Atop surface of the first portion 310 and a bottom surface 320BS of the second portion 320 that are in contact with each other may not have the same width in the second direction D2. The width of the top surface of the first portion 310 may be greater than the width of the bottom surface 320BS of the second portion 320. However, example embodiments are not limited thereto. The width of the top surface of the first portion 310 may be smaller than the width of the bottom surface 320BS of the second portion 320.

According to some example embodiments, the first portion 310 and the second portion 320 of the through via 300 may have different degrees of being tapered toward the backside pad 430. Specifically, the slope of the side surface of the first portion 310 may be different from the slope of the side surface of the second portion 320 in the second direction D2. As a distance from the backside pad 430 decreases, the width of the second portion 320 may more steeply decrease than the width of the first portion 310 may decrease in the second direction D2.

According to some example embodiments, a first via insulation layer 351 may surround the first portion 310. The first via insulation layer 351 may cover the side surface of the first portion 310. A second via insulation layer 352 may surround the second portion 320. The second via insulation layer 352 may cover the side surface of the second portion 320.

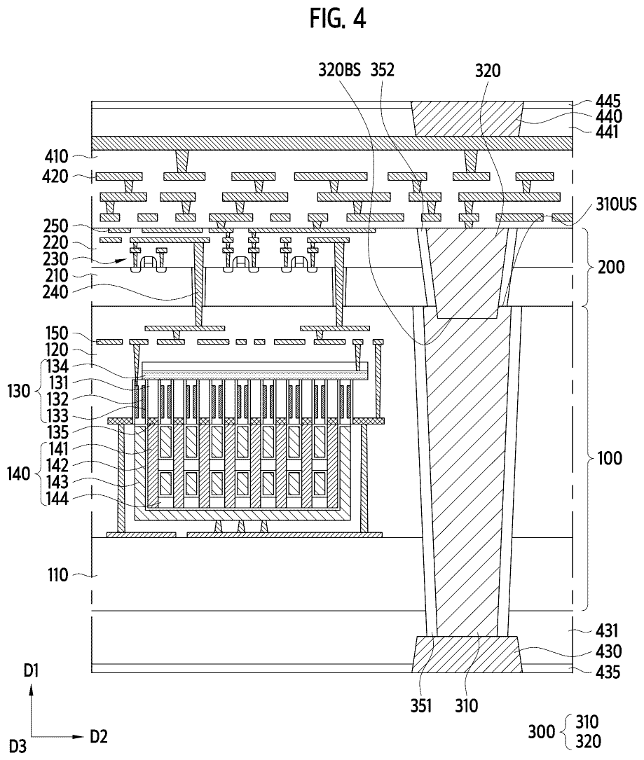

FIG. 4 is an exemplary enlarged view illustrating part P of FIG. 1 to explain a semiconductor chip according to other example embodiments. To explain a semiconductor chip according to other example embodiments, a difference from the description with reference to FIGS. 2 and 3 may be mainly described.

Referring to FIG. 4, at least a part of the second portion 320 may be inserted within the first portion 310. At least the part of the second portion 320 may overlap with the first portion 310 in the second direction D2. At least the part of the second portion 320 may be surrounded by the first portion 310 (e.g., when viewed from a plan view). The bottom surface 320BS of the second portion and a top surface 310US of the first portion may not be disposed on the same plane. The bottom surface 320BS of the second portion may be disposed lower than the top surface 310US of the first portion. The width of the bottom surface 320BS of the second portion may be smaller than the width of the top surface 310US of the first portion in the second direction D2.

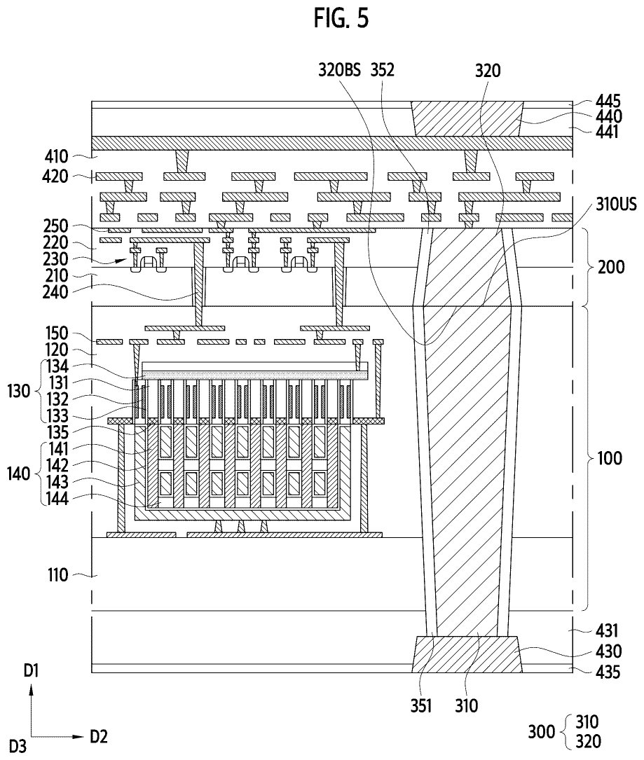

FIG. 5 is an exemplary enlarged view illustrating part P of FIG. 1 to explain a semiconductor chip according to other example embodiments. To explain a semiconductor chip according to other example embodiments, a difference from the description with reference to FIGS. 2 to 4 may be mainly described.

Referring to FIG. 5, in a direction moving toward the cell area 100, the width of the second portion 320 may increase in the second direction D2. In a direction moving toward the chip wiring structure 420, the width of the second portion 320 may decrease in the second direction D2. On the boundary surface of the cell area 100 and the peripheral circuit area 200, the side surface of the first portion 310 and the side surface of the second portion 320 may be joined in a predetermined angle. The width of the top surface 310US of the first portion and the width of the bottom surface 320BS of the second portion may be identical to each other in the second direction D2 where they meet. However, example embodiments are not limited thereto. For example, the width of the top surface 310US of the first portion and the width of the bottom surface 320BS of the second portion may be different from each other in the second direction D2.

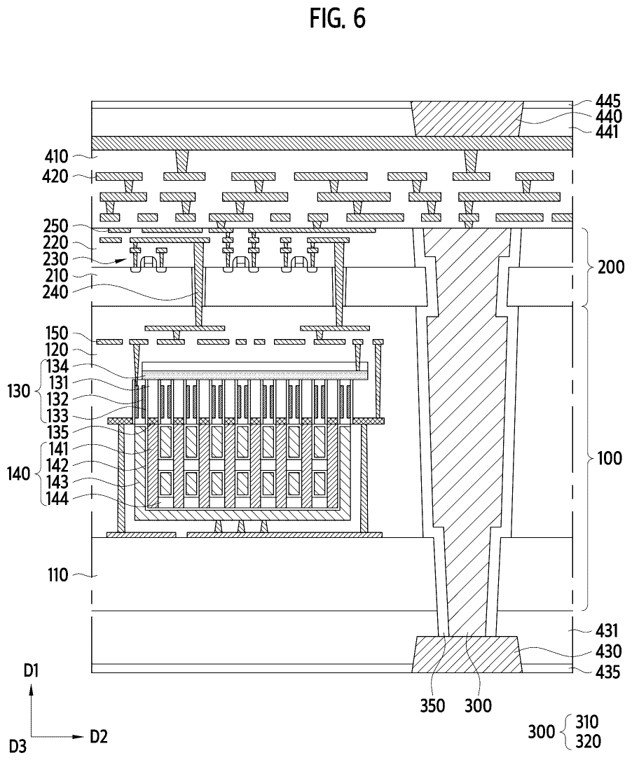

FIG. 6 is an exemplary enlarged view illustrating part P of FIG. 1 to explain a semiconductor chip according to other example embodiments. To explain a semiconductor chip according to other example embodiments, a difference from the description with reference to FIGS. 1 and 2 may be mainly explained.

Referring to FIG. 6, the width of portions of the through via 300 penetrating the cell substrate 110 and the peripheral circuit substrate 210 and the width of portions of the through via 300 penetrating the cell insulation layer 120 and the peripheral circuit insulation layer 220 may be different. The width of portions of the through via 300 penetrating the cell substrate 110 and the peripheral circuit substrate 210 in the second direction D2 may be smaller than the width of portions of the through via 300 penetrating the cell insulation layer 120 and the peripheral circuit insulation layer 220 in the second direction D2.

According to some example embodiments, the portion of the through via 300 overlapping with the cell substrate 110 and the peripheral circuit substrate 210 in the second direction D2 and the portions of the through via 300 overlapping with the cell insulation layer 120 and the peripheral circuit insulation layer 220 in the second direction D2 may be connected to each other with a step. The portions of the through via 300 overlapping with the cell substrate 110 and the peripheral circuit substrate 210 in the second direction D2 may be recessed inward more than the portions of the through via 300 overlapping with the cell insulation layer 120 and the peripheral circuit insulation layer 220 in the second direction D2. The portions of the through via 300 overlapping with the cell insulation layer 120 and the peripheral circuit insulation layer 220 in the second direction D2 may protrude outward more than the portions of the through via 300 overlapping with the cell substrate 110 and the peripheral circuit substrate 210 in the second direction D2.

According to some example embodiments, the side surface of the through via 300 may have a protrusion part and a recess part. For example, the side surface of the through via 300 may include a part protruding outward along the second direction D2 and a part recessed inside of the through via 300 along the second direction D2. It should be noted that the recesses and protrusions may also be formed in the third direction D3 in some embodiments. Within the cell insulation layer 120 and the peripheral circuit insulation layer 220, the side surface of the through via 300 may protrude outward more along the second direction D2 than the side surface of the through via 300 disposed within the cell substrate 110 and the peripheral circuit substrate 210. Within the cell substrate 110 and the peripheral circuit substrate 210, the side surface of the through via 300 may be recessed inward more along the second direction D2 than the side surface of the through via 300 disposed within the cell insulation layer 120 and the peripheral circuit insulation layer 220.

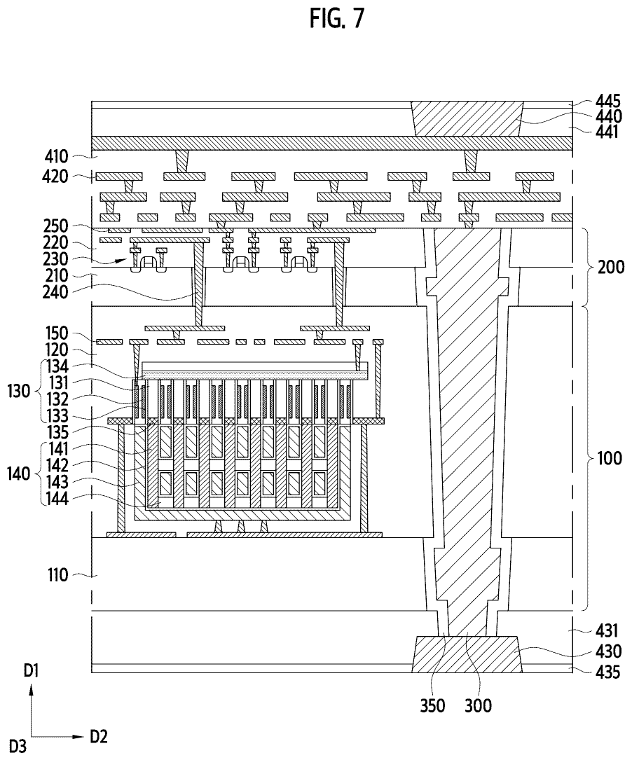

FIG. 7 is an exemplary enlarged view illustrating part P of FIG. 1 to explain a semiconductor chip according to other example embodiments. To explain a semiconductor chip according to other example embodiments, a difference from the description with reference to FIG. 6 may be mainly explained.

Referring to FIG. 7, the width of portions of the through via 300 penetrating the cell substrate 110 and the peripheral circuit substrate 210 in the second direction D2 may be greater than the width of portions of the through via 300 penetrating the cell insulation layer 120 and the peripheral circuit insulation layer 220 in the second direction D2.

According to some example embodiments, the portion of the through via 300 overlapping with the cell substrate 110 and the peripheral circuit substrate 210 in the second direction D2 and the portions of the through via 300 overlapping with the cell insulation layer 120 and the peripheral circuit insulation layer 220 in the second direction D2 may be connected to each other with a step. The portions of the through via 300 overlapping with the cell substrate 110 and the peripheral circuit substrate 210 in the second direction D2 may protrude further outside the through via 300 than the portions of the through via 300 overlapping with the cell insulation layer 120 and the peripheral circuit insulation layer 220 in the second direction D2. The portions of the through via 300 overlapping with the cell insulation layer 120 and the peripheral circuit insulation layer 220 in the second direction D2 may be recessed inward more than the portions of the through via 300 overlapping with the cell substrate 110 and the peripheral circuit substrate 210 in the second direction D2.

According to some example embodiments, the side surface of the through via 300 may have a protrusion part and a recess part. For example, the side surface of the through via 300 may include a part protruding outward along the second direction D2 and a part recessed inside of the through via 300 along the second direction D2. Within the cell substrate 110 and the peripheral circuit substrate 210, the side surface of the through via 300 may protrude outward more along the second direction D2 than the side surface of the through via 300 disposed within the cell insulation layer 120 and the peripheral circuit insulation layer 220. Within the cell insulation layer 120 and the peripheral circuit insulation layer 220, the side surface of the through via 300 may be recessed inward more along the second direction D2 than the side surface of the through via 300 disposed within the cell substrate 110 and the peripheral circuit substrate 210.

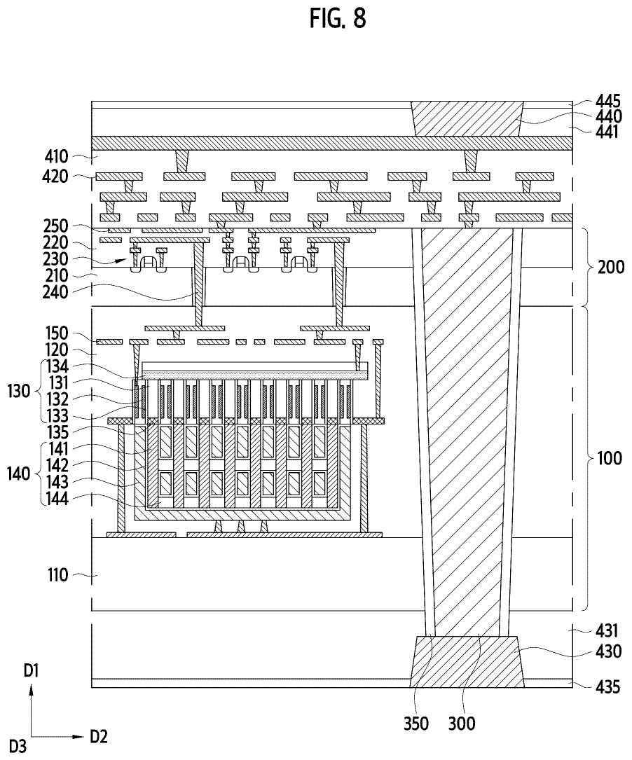

FIG. 8 is an exemplary enlarged view illustrating part P of FIG. 1 to explain a semiconductor chip according to other example embodiments. To explain a semiconductor chip according to other example embodiments, a difference from the description with reference to FIG. 2 may be mainly explained.

According to some example embodiments, the thickness of the backside pad 430 and the thickness of the frontside pad 440 in the first direction D1 may be different from each other. For example, the thickness of the backside pad 430 in the first direction D1 may be thicker than the thickness of the frontside pad 440. In FIG. 8, it is illustrated that the thickness of the backside pad 430 is thicker than the thickness of the frontside pad 440 in the first direction D1, but example embodiments are not limited thereto. For example, the thickness of the backside pad 430 may be thinner than the thickness of the frontside pad 440 in the first direction D1.

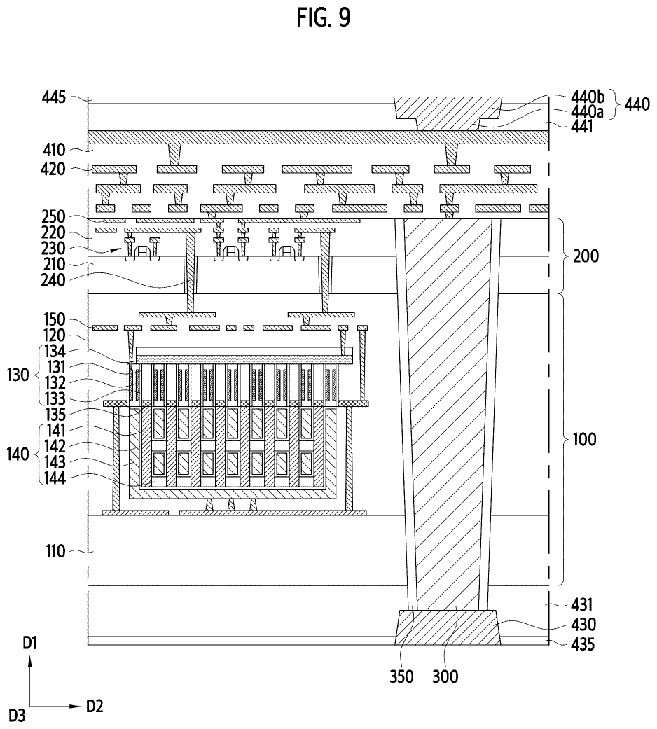

FIG. 9 is an exemplary enlarged view illustrating part P of FIG. 1 to explain a semiconductor chip according to other some example embodiments. To explain a semiconductor chip according to other some example embodiments, a difference from the description with reference to FIG. 2 may be mainly explained.

Referring to FIG. 9, the side surface of the frontside pad 440 may have a step. The frontside pad 440 may include a first pad portion 440a and a second pad portion 440b. The width of the first pad portion 440a and the width of the second pad portion 440b in the second direction D2 may be different from each other. The first pad portion 440a may be disposed more adjacent to the chip wiring structure 420 than the second pad portion 440b may be disposed. The width of the first pad portion 440a may be smaller than the width of the second pad portion 440b in the second direction D2. The frontside pad 440, for example, may be formed through a dual damascene process.

In FIG. 9, it is illustrated that only the frontside pad 440 includes the first pad portion 440a and the second pad portion 440b, but example embodiments are not limited thereto. The backside pad 430 may include a first pad portion and a second pad portion of different widths in the second direction D2.

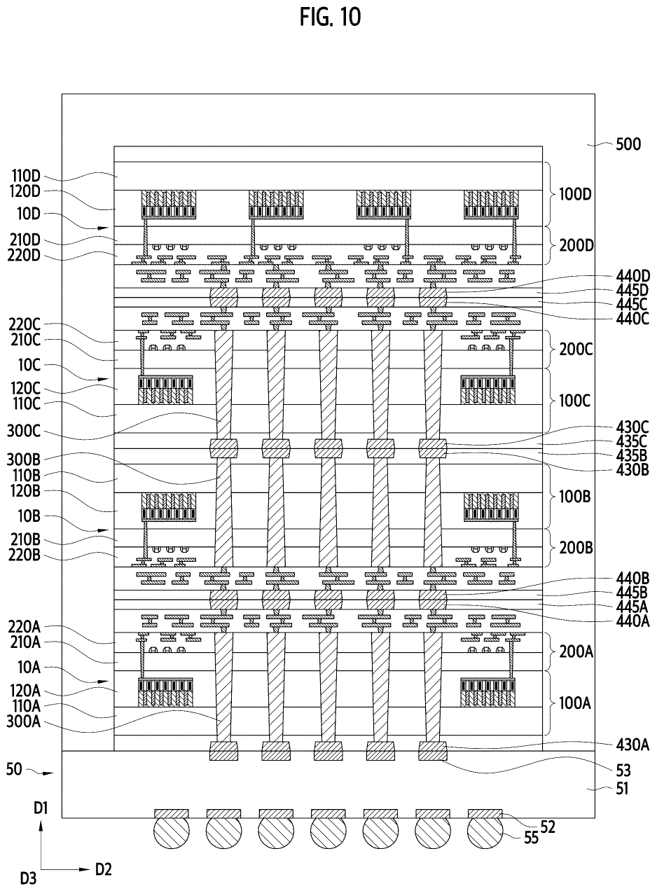

FIG. 10 is a schematic diagram illustrating a cross section of a semiconductor package according to some example embodiments.

Referring to FIG. 10, a semiconductor package according to some example embodiments may include a package die 50, a plurality of semiconductor chips 10A, 10B, 10C, and 10D, and a molding layer 500.

According to some example embodiments, the package die 50 may be disposed below the plurality of semiconductor chips 10A, 10B, 10C, and 10D. The package die 50 may be electrically connected to the plurality of semiconductor chips 10A, 10B, 10C, and 10D. The plurality of semiconductor chips 10A, 10B, 10C, and 10D may exchange an electrical signal with an external device through the package die 50.

According to some example embodiments, the package die 50 may be a wiring structure for a package. For example, the package die 50 may be a printed circuit board (PCB), a ceramic substrate, or an interposer. Alternatively, the package die 50 may also be a wiring structure for a wafer level package (WLP) that is manufactured at a wafer level. The package die 50 may be a semiconductor chip including a semiconductor element. The package die 50 may function as a support substrate of a semiconductor package. The package die 50 may be a buffer chip connected to the plurality of semiconductor chips 10A, 10B, 10C, and 10D.

In some example embodiments, the package die 50 may be a package substrate and may be a glass substrate, a ceramic substrate, or a plastic substrate, but is not limited thereto. For example, the package die 50 may include a resin, impregnated together with an inorganic filler in a core material such as glass fiber, glass cloth, glass fabric, and the like, for example, prepreg, ajinomoto build-up film (ABF), FR-4, or bismaleimide triazine (BT).

According to some example embodiments, the package die 50 may include, for example, bulk silicon or silicon-on-insulator (SOI). As another example, the package die 50 may be a silicon substrate. As another example, the package die 50 may include silicon germanium, silicon germanium on insulator (SGOI), indium antimonide, lead telluride, indium arsenide, indium phosphide, gallium arsenide, or gallium antimonide, but is not limited thereto.

According to some example embodiments, the package die 50 may include a conductive area, for example, an impurity-doped well or an impurity-doped structure. The package die 50 may have various element isolation structures such as an STI structure.

According to some example embodiments, the package die 50 may include a body part 51, a lower bonding pad 52, and an upper bonding pad 53.

According to some example embodiments, when the package die 50 is the PCB, the body part 51 may be composed of at least one material selected from phenol resin, epoxy resin, and polyimide. The package die 50 may include at least one selected material from tetrafunctional epoxy, polyphenylene ether, epoxy/polyphenylene oxide, BT, thermount, cyanate ester, and liquid crystal polymer.

According to some example embodiments, the body part 51 may include photoimageable dielectric. For example, the body part 51 may include photoimageable polymer. The photoimageable polymer may be formed, for example, as at least one of photoimageable polyimide, polybenzoxazole, phenolic polymer, and benzocyclobutene-based polymer. As another example, the body part 51 may be formed as a silicon oxide layer, a silicon nitride layer, or a silicon oxynitride layer.

Although not illustrated, a surface of the body part 51 may be covered by an upper insulation layer and a lower insulation layer. The upper insulation layer and the lower insulation layer may protect a substrate wiring structure and other structures within the body part 51 from an external shock or humidity. The upper insulation layer and the lower insulation layer may include a solder resist. However, example embodiments are not limited thereto.

According to some example embodiments, the lower portion bonding pad 52 may be disposed at a lower portion of the body part 51. The upper bonding pad 53 may be in contact with a first backside pad 430A of a first semiconductor chip 10A.

Although not illustrated, within the body part 51, a substrate wiring structure may be disposed. The substrate wiring structure may include a wiring layer and a wiring via connecting each wiring layer. For example, the substrate wiring structure may be a multi-layer structure where two or more wiring layers or two or more wiring vias are alternately stacked. For example, the wiring layer may extend in the second direction D2 or a direction that crosses the first direction D1 and the second direction D2. The wiring via may connect the wiring layers spaced apart in the first direction D1.

According to some example embodiments, the substrate wiring structure may include or be formed of a conductive material. For example, the substrate wiring structure may include or be formed of copper (Cu), aluminum (Al), silver (Ag), tin (Sn), gold (Au), nickel (Ni), lead (Pb), titanium (Ti), or an alloy thereof, but is not limited thereto.

According to some example embodiments, an external connecting terminal 55 may be formed under the package die 50. The external connecting terminal 55 may be disposed on the lower bonding pad 52. The external connecting terminal 55 may be in contact with the lower bonding pad 52. The external connecting terminal 55 may included or be a solder ball or a solder bump. The external connecting terminal 55 may be, for example, a globular shape or an oval shape, but not limited thereto. The number, an interval, an arrangement, and a shape of the external connecting terminal 55 may not be limited to what is illustrated and may also be various depending on design. The external connecting terminal 55 may include, for example, tin (Sn), indium (In), bismuth (Bi), antinomy (Sb), copper (Cu), silver (Ag), zinc (Zn), lead (Pb), and a combination thereof, but is not limited thereto.

According to some example embodiments, the external connecting terminal 55 may electrically connect the package die 50 to an external device. Accordingly, the external connecting terminal 55 may provide an electrical signal to the package die 50 or an electrical signal provided from the package die 50 to the external device. For example, the external connecting terminal 55 may be provided with a signal that is input to the plurality of semiconductor chips 10A, 10B, 10C, and 10D. The external connecting terminal 55 may be provided with a signal that is output from the plurality of semiconductor chips 10A, 10B, 10C, and 10D.

According to some example embodiments, the plurality of semiconductor chips 10A, 10B, 10C, and 10D may be stacked on the package die 50. The plurality of semiconductor chips 10A, 10B, 10C, and 10D may be stacked on the package die 50 in the first direction D1. Each of the plurality of the semiconductor chips 10A, 10B, 10C, and 10D may include a cell area 100A, 100B, 100C, or 100D, a peripheral circuit area 200A, 200B, 200C, or 200D, and a through via 300A, 300B, or 300C. The through vias 300A, 300B, and 300C included in the plurality of semiconductor chips 10A, 10B, and 10C may overlap with each other in the first direction D1. Items described as “overlapping” in a particular direction are arranged with respect to each other so that the items are both intersected by a straight line extending in the particular direction.

According to some example embodiments, each of the plurality of semiconductor chips 10A, 10B, 10C, and 10D may be a volatile memory chip such as dynamic random excess memory (DRAM) or static random access memory (SRAM). As another example, each of the plurality of semiconductor chips 10A, 10B, 10C, and 10D may be a nonvolatile memory chip such as flash memory, phase-change RAM (PRAM), magnetoresistive RAM (MRAM), ferroelectricRAM (FeRAM), or resistive RAM (RRAM). Each of the plurality of semiconductor chips 10A, 10B, 10C, and 10D may include a vertical channel transistor.

According to some example embodiments, the plurality of semiconductor chips 10A, 10B, 10C, and 10D may include a first semiconductor chip 10A, an additional second semiconductor chip 10B, an additional third semiconductor chip 10C, and an additional fourth semiconductor chip 10D. The first semiconductor chip 10A, the second semiconductor chip 10B, the third semiconductor chip 10C, and the fourth semiconductor chip 10D may be sequentially stacked on the package die 50 in the first direction D1.

According to some example embodiments, the first semiconductor chip 10A may include a first cell area 100A, a first peripheral circuit area 200A, and a first through via 300A. The first cell area 100A may include a first cell substrate 110A and a first cell insulation layer 120A. The first peripheral circuit area 200A may include a first peripheral circuit substrate 210A and a first peripheral circuit insulation layer 220A. The first through via 300A may penetrate the first cell substrate 110A, the first cell insulation layer 120A, the first peripheral circuit substrate 210A, and the first peripheral circuit insulation layer 220A in the first direction D1.

According to some example embodiments, each additional semiconductor chip may include additional components that may have the same structure and/or function as the components of the first semiconductor chip 10A. For example, the second semiconductor chip 10B may include a second cell area 100B, a second peripheral circuit area 200B, and a second through via 300B. The second cell area 100B may include a second cell substrate 110B and a second cell insulation layer 120B. The second peripheral circuit area 200B may include a second peripheral circuit substrate 210B and a second peripheral circuit insulation layer 220B. The second through via 300B may penetrate the second cell substrate 110B, the second cell insulation layer 120B, the second peripheral circuit substrate 210B, and the second peripheral circuit insulation layer 220B in the first direction D1.

According to some example embodiments, the third semiconductor chip 10C may include a third cell area 100C, a third peripheral circuit area 200C, and a third through via 300C. The third cell area 100C may include a third cell substrate 110C and a third cell insulation layer 120C. The third peripheral circuit area 200C may include a third peripheral circuit substrate 210C and a third peripheral circuit insulation layer 220C. The third through via 300C may penetrate the third cell substrate 110C, the third cell insulation layer 120C, the third peripheral circuit substrate 210C, and the third peripheral circuit insulation layer 220C in the first direction D1.

According to some example embodiments, the fourth semiconductor chip 10D, unlike the first semiconductor chip 10A, the second semiconductor chip 10B and the third semiconductor chip 10C, may not include a through via and a backside pad.

According to some example embodiments, the first semiconductor chip 10A, the second semiconductor chip 10B, the third semiconductor chip 10C, and the fourth semiconductor chip 10D may be connected to each other in a manner of hybrid bonding. For example, a first frontside pad 440A of the first semiconductor chip 10A and a second frontside pad 440B of the second semiconductor chip 10B may contact each other so that the first semiconductor chip 10A and the second semiconductor chip 10B are bonded. A first frontside bonding layer 445A of the first semiconductor chip 10A and a second frontside bonding layer 445B of the second semiconductor chip 10B may be directly bonded.

According to some example embodiments, the first frontside pad 440A and the second frontside pad 440B may be bonded so that the first semiconductor chip 10A and the second semiconductor chip 10B are physically and electrically connected. The first frontside bonding layer 445A of the first semiconductor chip 10A and the second frontside bonding layer 445B of the second semiconductor chip 10B may be bonded. The first frontside bonding layer 445A and the second frontside bonding layer 445B may be bonded through a N—H bond and an O—H bond, which may be caused by the first frontside bonding layer 445A and the second bonding layer 445B being bonded through a plasma process using N2 gas and O2 gas.

According to some example embodiments, the first peripheral circuit area 200A of the first semiconductor chip 10A and the second peripheral circuit area 200B of the second semiconductor chip 10B may face each other in the first direction D1. For example, a top surface of the first peripheral circuit area 200A of the first semiconductor chip 10A may face the bottom surface of the second peripheral circuit area 200B of the second semiconductor chip 10B. The first through via 300A of the first semiconductor chip 10A and the second through via 300B of the second semiconductor chip 10B may be electrically connected through the first frontside pad 440A and the second frontside pad 440B.

According some example embodiments, a second backside pad 430B of the second semiconductor chip 10B and a third backside pad 430C of the third semiconductor chip 10C may be contacted. The second backside pad 430B and the third backside pad 430C may be bonded so that the second semiconductor chip 10B and the third semiconductor chip 10C are connected. A second backside bonding layer 435B of the second semiconductor chip 10B and a third backside bonding layer 435C of the third semiconductor chip 10C may be bonded. The second backside bonding layer 435B and the third backside bonding layer 435C may be bonded through a N—H bond and an O—H bond, which may be caused by the second backside bonding layer 435B and the third backside bonding layer 435C being bonded through a plasma process using N2 gas and O2 gas.

According to some example embodiments, the second cell area 100B of the second semiconductor chip 10B and the third cell area 100C of the third semiconductor chip 10C may face each other in the first direction D1. For example, a top surface of the second cell area 100B of the second semiconductor chip 10B may face a bottom surface of the third cell area 100C of the third semiconductor chip 10C. The second through via 300B of the second semiconductor chip 10B and the third through via 300C of the third semiconductor chip 10C may be electrically connected through the second backside pad 430B and the third backside pad 430C.

According to some example embodiments, a third frontside pad 440C of the third semiconductor chip 10C and a fourth frontside pad 440D of the fourth semiconductor chip 10D may contact each other. The third frontside pad 440C and the fourth frontside pad 440D may be bonded so that the third semiconductor chip 10C and the fourth semiconductor chip 10D are connected. A third frontside bonding layer 445C of the third semiconductor chip 10C and a fourth frontside bonding layer 445D of the fourth semiconductor chip 10D may be bonded. The third frontside bonding layer 445C and the fourth frontside bonding layer 445D may be bonded through a N—H bond and an O—H bond, which may be caused by the third frontside bonding layer 445C and the fourth frontside bonding layer 445D being bonded through a plasma process using N2 gas and O2 gas.

According to some example embodiments, the third peripheral circuit area 200C of the third semiconductor chip 10C and the fourth peripheral circuit area 200D of the fourth semiconductor chip 10D may face each other in the first direction D1.

According to some example embodiments, some of the plurality of semiconductor chips 10A, 10B, 10C, and 10D may be bonded through the frontside pads 440A, 440B, 440C, and 440D, and some thereof may be bonded through the backside pads 430B and 430C. For example, as the first frontside pad 440A of the first semiconductor chip 10A and the second frontside pad 440B of the second semiconductor chip 10B are bonded, each of the front sides of the first semiconductor chip 10A and the second semiconductor chip 10B may be bonded. A direction in which the first semiconductor chip 10A is stacked in the first direction D1 and a direction in which the second semiconductor chip 10B is stacked in the first direction D1 may be opposite, so that certain components may have mirror symmetry with respect to each other across a plane formed where the two semiconductor chips are bonded to each other. For another example, as the second backside pad 430B of the second semiconductor chip 10B and the third backside pad 430C of the third semiconductor chip 10C are bonded, each of the back sides of the second semiconductor chip 10B and the third semiconductor chip 10C may be bonded. Therefore, a direction in which the second semiconductor 10B chip is stacked in the first direction D1 and a direction in which the third semiconductor chip 10C is stacked in the first direction D1 may be opposite. As described, the directions in which the plurality of semiconductor chips 10A, 10B, 10C, and 10D are stacked in the first direction D1 may be disposed opposite to each other, which may decrease a risk of warpage, which occurs when the plurality of semiconductor chips 10A, 10B, 10C, and 10D are stacked in the same direction so that the plurality of semiconductor chips 10A, 10B, 10C, and 10D are warped. According to example embodiments of the present disclosure, it is possible to decrease a risk of warpage of a semiconductor package.

According to some example embodiments, since the plurality of the semiconductor chips 10A, 10B, 10C, and 10D are substantially identical to the semiconductor chip 10 described with reference to FIGS. 1 to 9, the description of the plurality of semiconductor chips 10A, 10B, 10C, and 10D is omitted hereinafter. In FIG. 10, four semiconductor chips 10A, 10B, 10C, and 10D are illustrated as being stacked, but example embodiments are not limited thereto. The number of the semiconductor chips 10A, 10B, 10C, and 10D being stacked may vary depending on example embodiments.

According to some example embodiments, the molding layer 500 may be formed on the package die 50. The molding layer 500 may cover the plurality of semiconductor chips 10A, 10B, 10C, and 10D. The molding layer 500 may include, for example, polymer such as resin. For example, the molding layer 500 may include epoxy molding compound (EMC), but is not limited thereto.

Though a particular example type of through via is shown to be used in the various semiconductor chips of FIG. 10 (e.g., the type shown in FIGS. 1 and 2A and 2B), the semiconductor chips of FIG. 10 can have any of the different through vias described in connection with FIGS. 1, 2A, 2B, and 3-9.

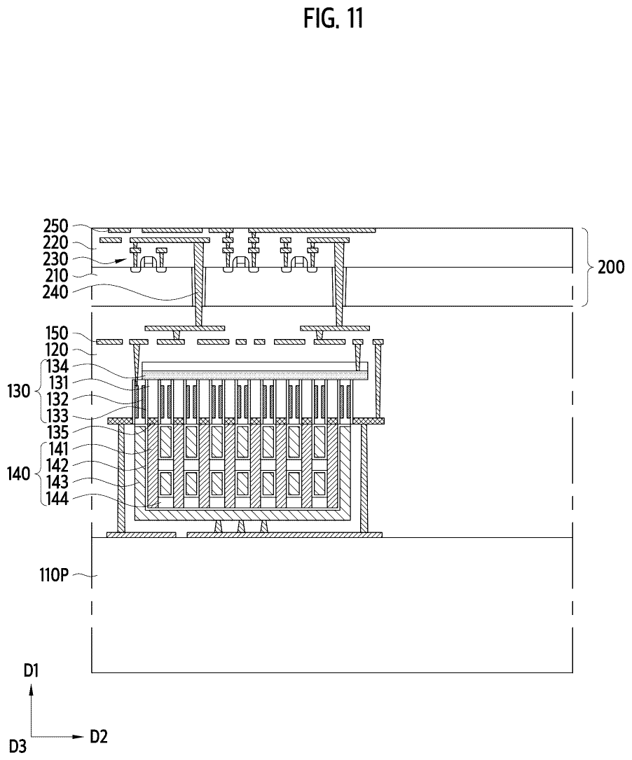

FIGS. 11 to 15 are exemplary diagrams illustrating an intermediate operation to explain a method for manufacturing of the semiconductor chip shown in FIG. 2.

Referring to FIG. 11, above a pre-cell substrate 110P, the cell insulation layer 120 and the peripheral circuit area 200 may be formed.

According to some example embodiments, the vertical channel transistor 130, the capacitor 140, and the cell wiring 150 may be formed within the cell insulation layer 120 above the pre-cell substrate 110P. On the peripheral circuit substrate 210, the peripheral circuit element 230, the peripheral circuit wiring 250 and the peripheral circuit insulation layer 220 may be formed. Subsequently, above the pre-cell substrate 110P, the peripheral circuit substrate 210 may be bonded. Specifically, on the cell insulation layer 120 where the vertical channel transistor 130, the capacitor 140, and the cell wiring 150 are formed, the peripheral circuit substrate 210 where the peripheral circuit element 230, the peripheral circuit wiring 250 and the peripheral circuit insulation layer 220 are formed may be bonded.

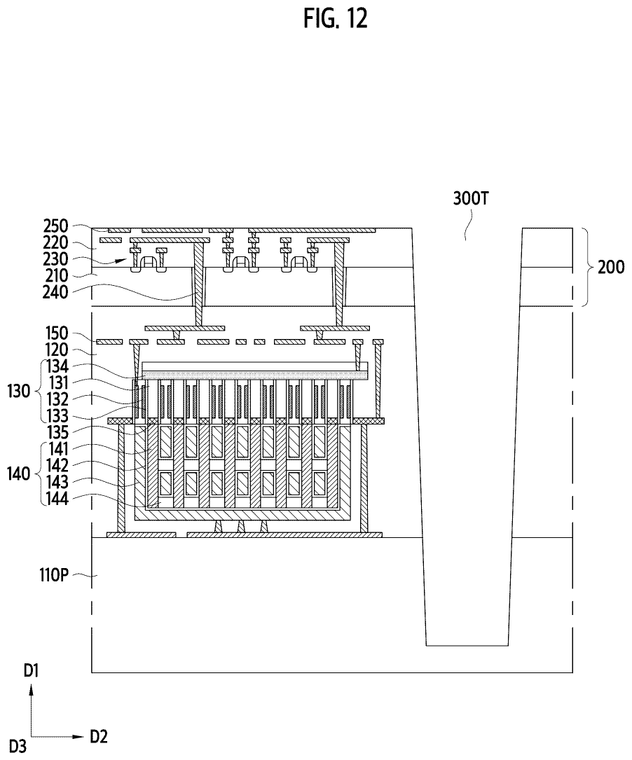

Referring to FIG. 12, a through via trench 300T penetrating at least a part of the pre-cell substrate 110P, the cell insulation layer 120, the peripheral circuit substrate 210, and the peripheral circuit insulation layer 220 is formed. The through via trench 300T may not completely penetrate the pre-cell substrate 110P. The through via trench 300T may be formed as at least parts of the pre-cell substrate 110P, the cell insulating layer 120, the peripheral circuit substrate 210 and the peripheral circuit insulation layer 220 are removed. From a plan view, the through via trench 300T may have a circular or polygonal shape, though other shapes may be used.

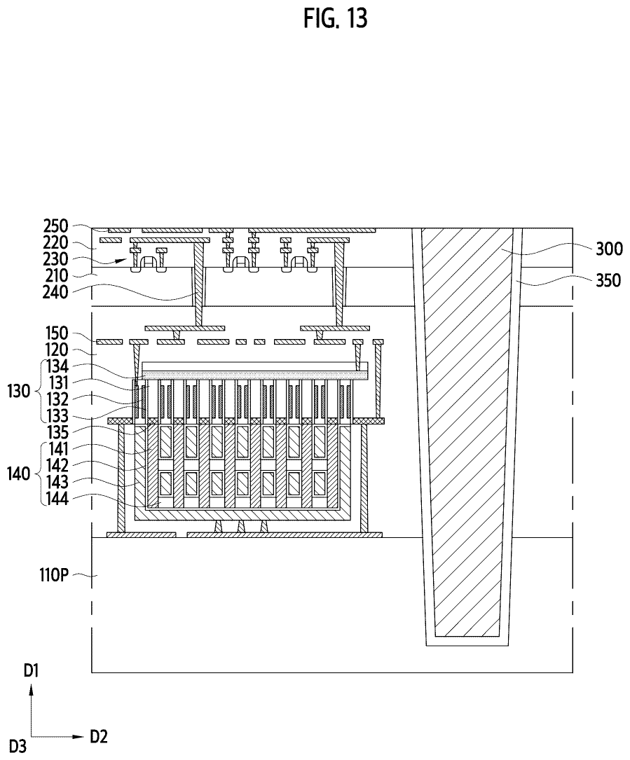

Referring to FIG. 13, the via insulation layer 350 and the through via 300 are formed within the through via trench 300T of FIG. 12. The via insulation layer 350 may extend along a bottom surface and a side surface of the through via trench 300T in FIG. 12. The through via 300 may be formed on the via insulation layer 350. The via insulation layer 350 and the through via 300 may fill the through via trench 300T of FIG. 12.

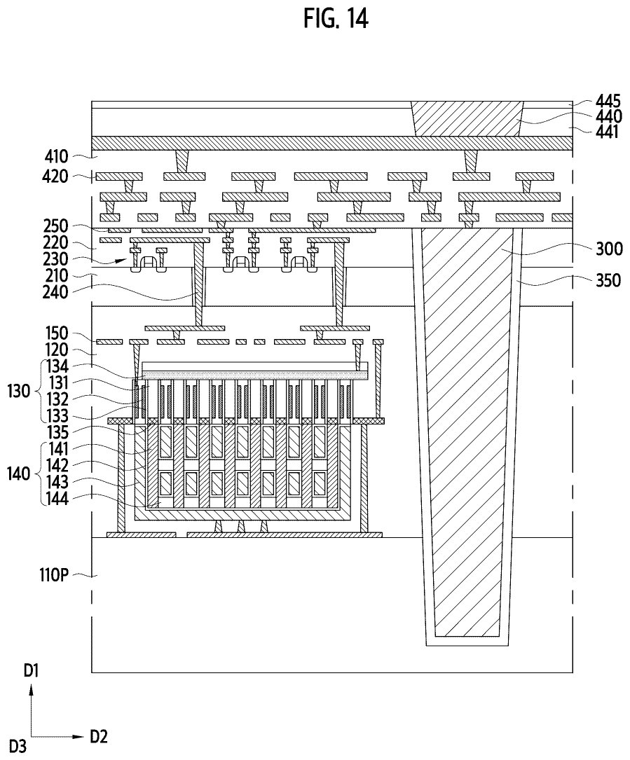

Referring to FIG. 14, the interlayer insulation layer 410 and the chip wiring structure 420 are formed on the peripheral circuit area 200. The frontside passivation layer 441, the frontside bonding layer 445, and the frontside pad 440 are formed above the interlayer insulation layer 410 and the chip wiring structure 420.

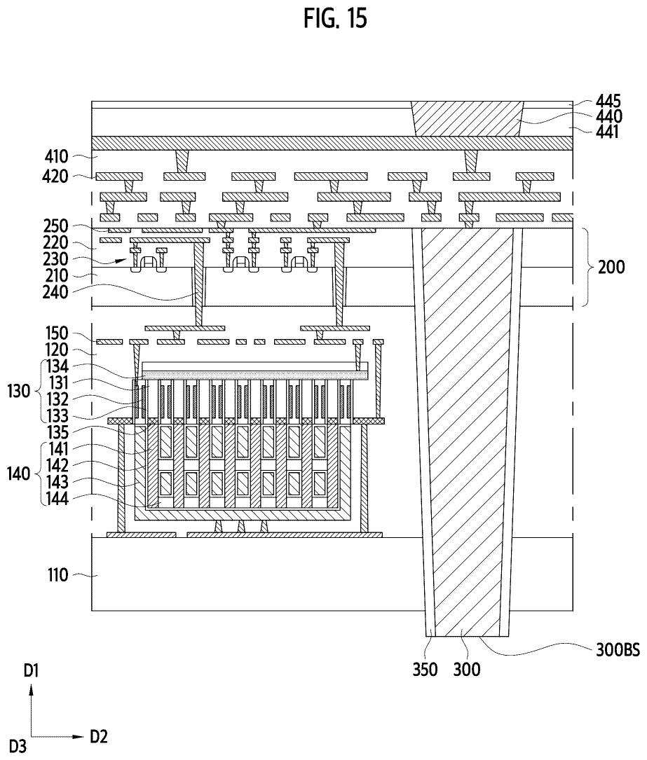

Referring to FIG. 15, the cell substrate 110 may be formed as a part of the pre-cell substrate 110P of FIG. 14 is removed to expose a bottom surface 300BS of the through via. The through via 300 may protrude below the cell substrate 110.

Subsequently, referring to FIG. 2, the backside passivation layer 431, the backside bonding layer 435, and the backside pad 430 may be formed below the cell substrate 110.

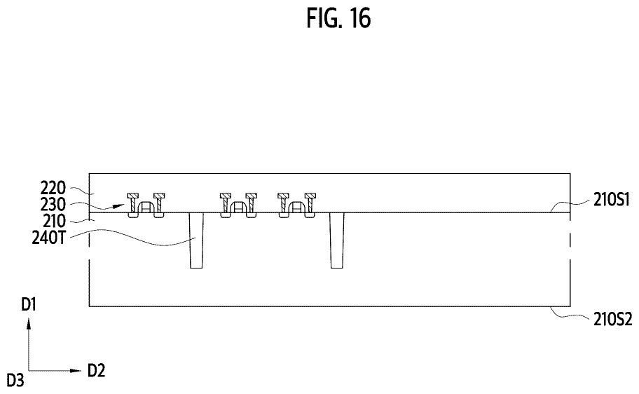

FIGS. 16 to 22 are exemplary diagrams illustrating an intermediate operation to explain a method for manufacturing of the semiconductor chip shown in FIG. 5. For the convenience of explanation, a difference from the description with reference to FIGS. 11 to 15 may be mainly explained.

Referring to FIG. 16, the peripheral circuit element 230 and the peripheral circuit insulation layer 220 are formed on the peripheral circuit substrate 210. The peripheral circuit insulation layer 220 and the peripheral circuit element 230 may be formed on a first surface 210S1 of the peripheral circuit substrate. The peripheral circuit insulation layer 220 may cover the first surface 210S1 of the peripheral circuit substrate. A connecting via trench 240T may be formed within the peripheral circuit substrate 210. The connecting via trench 240T may be formed toward a second surface 210S2 from the first surface 210S1 of the peripheral circuit substrate. An insulation layer may be formed within the connecting via trench 240T. The second surface 210S2 of the peripheral circuit substrate may refer to a surface disposed opposite in the first direction D1 to the first surface 210S1 on which the peripheral circuit insulation layer 220 and the peripheral circuit element 230 are disposed.

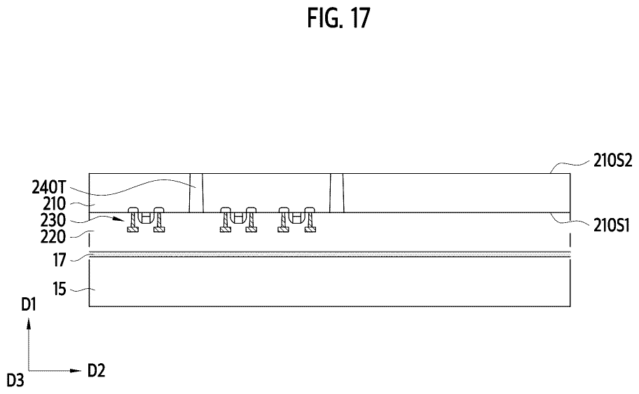

Referring to FIG. 17, the peripheral circuit substrate 210 and the peripheral circuit insulation layer 220 are bonded above a carrier substrate 15. Specifically, the peripheral circuit insulation layer 220 may be bonded above the carrier substrate 15 through a carrier bonding layer 17 so that the carrier substrate 15 and the first surface 210S1 of the peripheral circuit substrate face each other. A part of the peripheral circuit substrate 210 may be removed on the second surface 210S2 of the peripheral circuit substrate to expose the connecting via trench 240T above the carrier substrate 15. The insulation layer within the connecting via trench 240T may be exposed through the second surface 210S2 of the peripheral circuit substrate.

According to some example embodiments, the carrier bonding layer 17 may be formed with different materials among silicon oxide, silicon nitride, silicon carbonitride, and silicon oxycarbonitride. The carrier bonding layer 17 may include a non-conductive film (NCF), a non-conductive paste (NCP), an insulating polymer, or an epoxy resin, but is not limited thereto. The carrier bonding layer 17 may be a tape that mutually fixes the carrier substrate 15 and the peripheral circuit insulation layer 220. The carrier bonding surface 17 may be, for example, a tape including epoxy component.

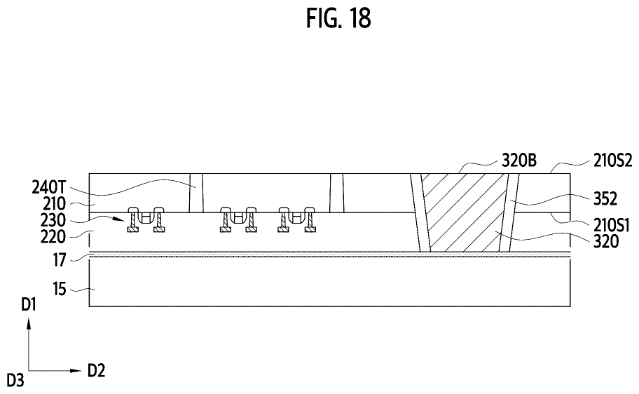

Referring to FIG. 18, the second portion 320 penetrating the peripheral circuit substrate 210 and the peripheral circuit insulation layer 220 are formed. Specifically, a part of the peripheral circuit substrate 210 and a part of the peripheral circuit insulation layer 220 may be removed to form a trench of the second portion 320. The second via insulation layer 352 within the trench may be formed on a side surface of the trench, and the second portion 320 may be formed on the second via insulation layer 352 to fill the trench. A bonding surface 320B of the second portion 320 may be exposed outside of the peripheral circuit substrate 210. The bonding surface 320B of the second portion 320 may be disposed on the same plane as the second surface 210S2 of the peripheral circuit substrate 210.

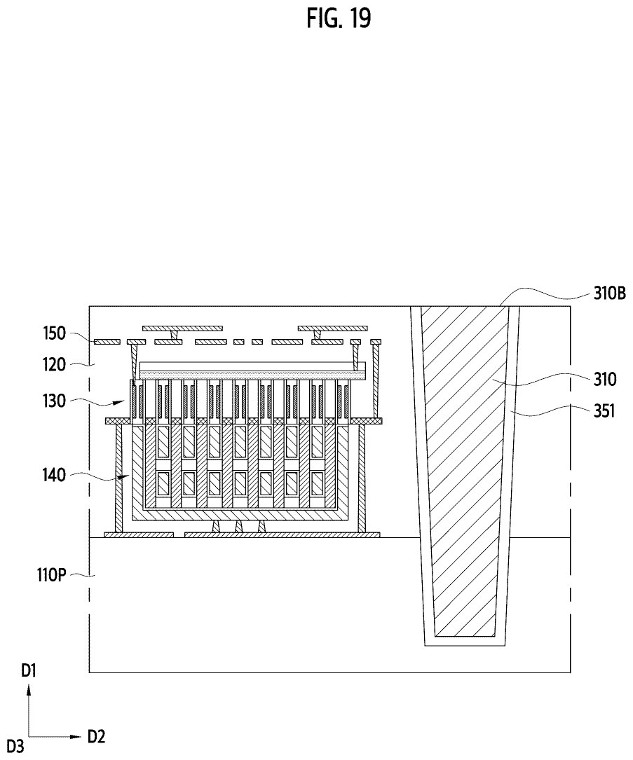

Referring to FIG. 19, the memory cells 130 and 140, the cell wiring 150, and the cell insulation layer 120 are formed above the pre-cell substrate 110P. Subsequently, the first portion 310 penetrating at least a part of the pre-cell substrate 110P and the cell insulation layer 120 may be formed. Specifically, a trench of the first portion 310 penetrating at least the part of the pre-cell substrate 110P and the cell insulation layer 120 may be formed. Within the trench, the first via insulation layer 351 may be formed to cover a bottom surface and a side surface of the trench, and the first portion 310 may be formed to fill the trench on the first via insulation layer 351. A bonding surface 310B of the first portion 310 may be exposed, not being covered by the cell insulation layer 120. The bonding surface 310B of the first portion 310 may be disposed on the same plane as one surface of the cell insulation layer 120.

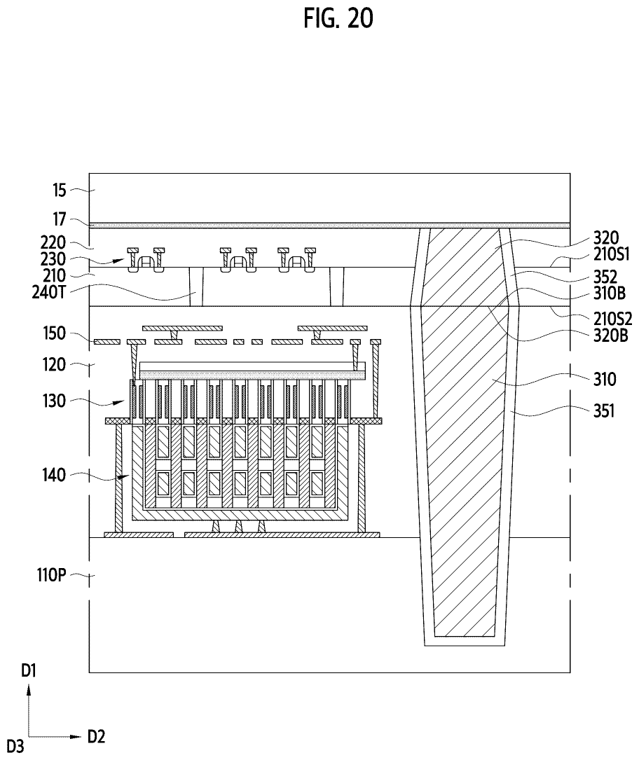

Referring to FIG. 20, the cell insulation layer 120 and the peripheral circuit substrate 210 are bonded. Specifically, the cell insulation layer 120 and the peripheral circuit substrate 210 contact each other so that the second surface 210S2 of the peripheral circuit substrate faces the cell insulation layer 120 in the first direction D1. The carrier substrate 15 may be disposed above the cell insulation layer 120, the peripheral circuit substrate 210, and the peripheral circuit insulation layer 220.

According to some example embodiments, the bonding surface 310B of the first portion 310 and the bonding surface 320B of the second portion 320 are brought into contact. As the cell insulation layer 120 and the second surface 21052 of the peripheral circuit substrate are in contact, the bonding surface 310B of the first portion 310 and the bonding surface 320B of the second portion 320 may be bonded to each other.

According to some example embodiments, before the peripheral circuit substrate 210 is bonded above the pre-cell substrate 110P, the first portion 310 and the second portion 320 may be formed. As the peripheral circuit substrate 210 is bonded above the pre-cell substrate 110P, the first portion 310 and the second portion 320 may be connected.

Unlike what is illustrated in FIGS. 18 and 20, before the peripheral circuit substrate 210 is bonded above the pre-cell substrate 110P, the first portion 310 may be formed, and after the peripheral circuit substrate 210 is bonded above the pre-cell substrate 110P, the second portion 320 may be formed. In this case, the peripheral circuit substrate 210 and the peripheral circuit insulation layer 220 may be bonded on the first portion 310, and as a part of the peripheral circuit substrate 210 and a part of the peripheral circuit insulation layer 220 are removed to expose the first portion 310, the trench of the second portion 320 may be formed. Subsequently, the second portion 320 may be formed within the trench of the second portion 320 to be connected to the first portion 310.

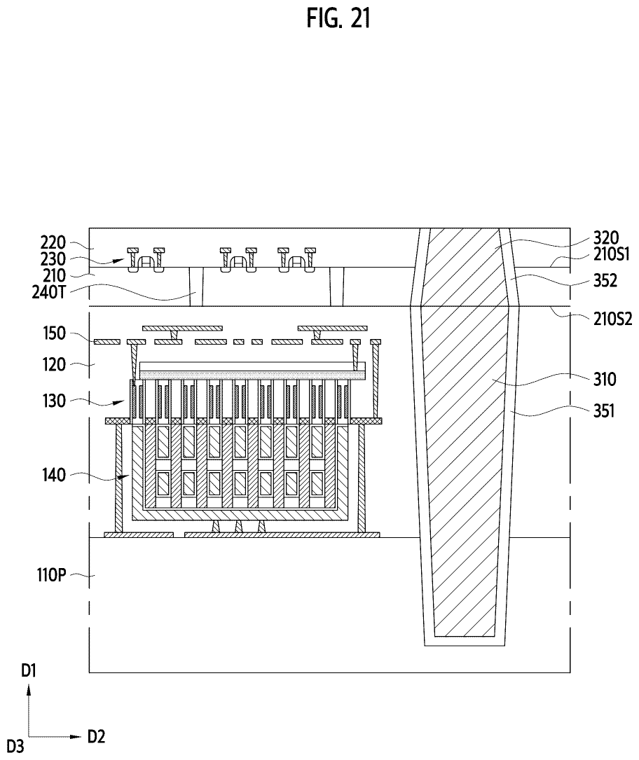

Referring to FIG. 21, the carrier bonding layer 17 of FIG. 20 and the carrier substrate 15 of FIG. 20 are removed. The peripheral circuit insulation layer 220 and a top surface of the second portion 320 are exposed.

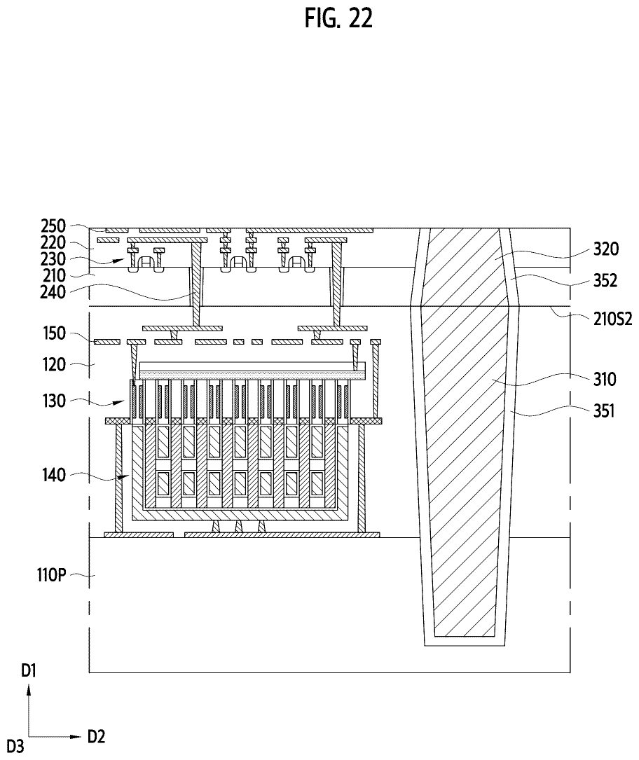

Referring to FIG. 22, the connecting via 240 and the peripheral circuit wiring 250 are formed within the peripheral circuit insulation layer 220. The connecting via 240 may penetrate the insulation layer within the connecting via trench 240T of FIG. 21. Operations after FIG. 22 are substantially identical to the description with reference to FIGS. 16 and 17, and thus, are omitted.

While some example embodiments of the present disclosure are explained in detail above, it is to be understood by those of ordinary skill in the art that the scope of a right of the present disclosure is not limited thereto, but, on the contrary, is intended to cover various modifications and equivalent arrangements included within the spirit and scope of the appended claims. In addition, some elements in aforementioned example embodiments may be deleted to be embodied, and each example embodiment may be combined to be embodied.

What is claimed is:

1. A semiconductor device comprising:
a semiconductor chip including:
a cell area including a memory cell;
a peripheral circuit area stacked on the cell area in a first direction and including a peripheral circuit element electrically connected to the memory cell;
a through via penetrating the cell area and the peripheral circuit area in the first direction;
a backside pad disposed below the cell area and electrically connected to the through via; and
a frontside pad disposed above the peripheral circuit area and electrically connected to the through via,
wherein the cell area comprises a cell insulation layer surrounding the memory cell and a cell substrate disposed below the cell insulation layer,
wherein the peripheral circuit area comprises:
a peripheral circuit insulation layer surrounding the peripheral circuit element and a peripheral circuit substrate disposed below the peripheral circuit insulation layer, so that the peripheral circuit substrate is between the peripheral circuit insulation layer and the cell insulation layer, and
wherein the through via penetrates the cell substrate, the cell insulation layer, the peripheral circuit substrate, and the peripheral circuit insulation layer along the first direction.

2. The semiconductor device of claim 1, further comprising:
a chip wiring structure disposed on the peripheral circuit area and electrically connected to the frontside pad and the through via.

3. The semiconductor device of claim 2, wherein the chip wiring structure is disposed between the frontside pad and the through via in the first direction.

4. The semiconductor device of claim 1, wherein a portion of the through via overlapping the cell insulation layer or the peripheral circuit insulation layer in a second direction that crosses the first direction protrudes outward more than a portion of the through via overlapping the cell substrate or the peripheral circuit substrate in the second direction.

5. The semiconductor device of claim 1, wherein a portion of the through via overlapping the cell substrate or the peripheral circuit substrate in a second direction that crosses the first direction protrudes outward more than a portion of the through via overlapping the cell insulation layer or the peripheral circuit insulation layer in the second direction.

6. The semiconductor device of claim 1, wherein the through via includes:
a first portion penetrating the cell area; and
a second portion that is connected to the first portion in the first direction and penetrates the peripheral circuit area, and
wherein a width of the first portion in a second direction that crosses the first direction decreases as a distance from the peripheral circuit area increases.

7. The semiconductor device of claim 1, wherein the semiconductor chip is a first semiconductor chip, and further comprising:
a package substrate below the semiconductor chip; and
a second semiconductor chip stacked on and above the first semiconductor chip, the second semiconductor chip comprising:
an additional cell area including an additional memory cell;
an additional peripheral circuit area stacked on the additional cell area in the first direction,
and including an additional peripheral circuit element electrically connected to the additional memory cell, so that the additional peripheral circuit area is between the first semiconductor chip and the additional cell area;
an additional through via penetrating the additional cell area and the additional peripheral circuit area in the first direction;
an additional frontside pad connected to the frontside pad, disposed below the additional peripheral circuit area and between the additional peripheral circuit area and the frontside pad, and electrically connected to the additional through via; and
an additional backside pad disposed above the additional cell area and electrically connected to the additional through via.

8. The semiconductor device of claim 7, wherein the additional through via includes:
a first portion penetrating the additional cell area; and
a second portion that is connected to the first portion in the first direction and penetrates the additional peripheral circuit area, and
wherein a width of the first portion in the second direction decreases as a distance from the first semiconductor chip increases.

9. The semiconductor device of claim 7, wherein:
the additional backside pad contacts the additional through via; and
the additional frontside pad is bonded to the frontside pad.

10. The semiconductor device of claim 7, wherein:
the additional cell area comprises an additional cell insulation layer surrounding the additional memory cell and an additional cell substrate disposed above the additional cell insulation layer,
wherein the additional peripheral circuit area comprises:
an additional peripheral circuit insulation layer surrounding the additional peripheral circuit element and an additional peripheral circuit substrate disposed above the additional peripheral circuit insulation layer, so that the additional peripheral circuit substrate is between the additional peripheral circuit insulation layer and the additional cell insulation layer, and
wherein the additional through via penetrates the additional cell substrate, the additional cell insulation layer, the additional peripheral circuit substrate, and the additional peripheral circuit insulation layer along the first direction.

11. The semiconductor device of claim 6, wherein a width of the second portion in the second direction increases as a distance from the cell area decreases.

12. The semiconductor device of claim 6, wherein at least a part of the second portion is inserted within the first portion.

13. The semiconductor device of claim 1, wherein the cell substrate, the cell insulation layer, the peripheral circuit substrate, and the peripheral circuit insulation layer are sequentially stacked from bottom to top in the first direction.

14. The semiconductor device of claim 1, wherein the through via has a step on a boundary surface of the cell area and the peripheral circuit area.

15. The semiconductor device of claim 1, wherein a thickness of the frontside pad and a thickness of the backside pad in the first direction are different from each other.

16. The semiconductor device of claim 1, wherein the memory cell includes a vertical channel transistor.

17. The semiconductor device of claim 16, wherein the cell area further includes a capacitor electrically connected to the vertical channel transistor.

18. The semiconductor device of claim 1, wherein the cell insulation layer and the peripheral circuit insulation layer include a different material from the cell substrate and the peripheral circuit substrate, respectively.

19. The semiconductor device of claim 1, further comprising:
a via insulation layer surrounding a side surface of the through via.

20. The semiconductor device of claim 1, further comprising:
a frontside bonding layer disposed above the peripheral circuit area and penetrated by at least a part of the frontside pad; and
a backside bonding layer disposed below the cell area and penetrated by at least of a part of the backside pad, and
wherein the frontside bonding layer includes a different material from the backside bonding layer.

21. A semiconductor device comprising:
a package substrate;
a first semiconductor chip on the package substrate; and
a second semiconductor chip bonded to the first semiconductor chip and disposed on the first semiconductor chip in a first direction,
wherein the first semiconductor chip comprises:
a first cell area including a memory cell;
a first peripheral circuit area that includes a peripheral circuit element and is arranged with the first cell area in the first direction;
a first through via penetrating the first cell area and the first peripheral circuit area;
a first backside pad that faces the first cell area so that the first cell area is at a vertical level between the first backside pad and the first peripheral circuit area, and is connected to the first through via; and
a first frontside pad that faces the first peripheral circuit area so that the first peripheral circuit area is at a vertical level between the first frontside pad and the first cell area, and is electrically connected to the first through via,
wherein the second semiconductor chip comprises:
a second cell area including a memory cell;
a second peripheral circuit area that includes a peripheral circuit element and is arranged with the second cell area in the first direction;
a second through via penetrating the second cell area and the second peripheral circuit area;
a second backside pad that faces the second cell area so that the second cell area is at a vertical level between the second backside pad and the second peripheral circuit area, and is connected to the second through via; and
a second frontside pad that faces the second peripheral circuit area so that the second peripheral circuit area is at a vertical level between the second frontside pad and the second cell area, and is electrically connected to the second through via,
wherein the first frontside pad and the second frontside pad are bonded to each other,
wherein the first cell area comprises a first cell substrate and a first cell insulation layer,
wherein the first peripheral circuit area comprises a first peripheral circuit substrate and a first peripheral circuit insulation layer,
wherein the first through via penetrates the first cell substrate, the first cell insulation layer,
the first peripheral circuit substrate and the first peripheral circuit insulation layer along the first direction,
wherein the second cell area comprises a second cell substrate and a second cell insulation layer,
wherein the second peripheral circuit area comprises a second peripheral circuit substrate and a second peripheral circuit insulation layer, and
wherein the second through via penetrates the second cell substrate, the second cell insulation layer, the second peripheral circuit substrate, and the second peripheral circuit insulation layer along the first direction.

22. The semiconductor device of claim 21, further comprising:
a third semiconductor chip bonded to the second semiconductor chip and disposed on the second semiconductor chip in the first direction,
wherein the third semiconductor chip comprises:
a third cell area including a memory cell;
a third peripheral circuit area that includes a peripheral circuit element and is arranged with the third cell area in the first direction;
a third through via penetrating the third cell area and the third peripheral circuit area;
a third backside pad that faces the third cell area and is connected to the third through via; and
a third frontside pad that faces the third peripheral circuit area and is electrically connected to the third through via, and
wherein the second backside pad and the third backside pad are bonded to each other.

23. The semiconductor device of claim 21,
wherein the first semiconductor chip further includes a first frontside bonding layer that is penetrated by the first frontside pad and faces the second semiconductor chip,
wherein the second semiconductor chip further includes a second frontside bonding layer that is penetrated by the second frontside pad, faces the first semiconductor chip, and is bonded to the first frontside bonding layer, and
wherein the first frontside bonding layer and the second frontside bonding layer are bonded through a N—H bond and an O—H bond.

24. A semiconductor device comprising:
a first semiconductor chip;
a second semiconductor chip bonded to the first semiconductor chip and disposed on the first semiconductor chip in a first direction; and
a third semiconductor chip bonded the second semiconductor chip and disposed on the second semiconductor chip in the first direction,
wherein the first semiconductor chip comprises:
a first cell area including a vertical channel transistor;
a first peripheral circuit area that includes a peripheral circuit element electrically connected to the vertical channel transistor of the first cell area and is arranged with the first cell area in the first direction; and
a first through via penetrating the first cell area and the first peripheral circuit area,
wherein the second semiconductor chip comprises:
a second cell area comprising a vertical channel transistor;
a second peripheral circuit area that includes a peripheral circuit element electrically connected to the vertical channel transistor of the second cell area and is arranged with the second cell area in the first direction; and
a second through via penetrating the second cell area and the second peripheral circuit area,
wherein the third semiconductor chip comprises:
a third cell area including a vertical channel transistor;
a third peripheral circuit area that includes a peripheral circuit element electrically connected to the vertical channel transistor of the third cell area and is arranged with the third cell area in the first direction; and
a third through via penetrating the third cell area and the third peripheral circuit area,
wherein, in the first direction, a top of the first peripheral circuit area faces a bottom of the second peripheral circuit area, and
wherein, in the first direction, a top of the second cell area faces a bottom of the third cell area.

25. A method for manufacturing a semiconductor chip, the method comprising:
forming a memory cell and a cell insulation layer covering the memory cell on a cell substrate;
forming a peripheral circuit element and a peripheral circuit insulation layer covering the peripheral circuit element on a peripheral circuit substrate;
disposing the peripheral circuit substrate on the cell substrate and bonding the peripheral circuit substrate to the cell substrate;
forming a through via penetrating the cell substrate and the peripheral circuit substrate;
forming a chip wiring structure electrically connected to the through via and the peripheral circuit element on the through via and the peripheral circuit element;
forming a frontside pad electrically connected to the chip wiring structure on the chip wiring structure; and
forming a backside pad connected to the through via below the cell substrate and the through via.

26. The method of claim 25,
wherein the through via includes:
a first portion penetrating the cell substrate and the cell insulation layer; and
a second portion penetrating the peripheral circuit substrate and the peripheral circuit insulation layer, and
wherein forming the through via comprises:
before bonding the peripheral circuit substrate on the cell substrate, forming the first portion penetrating the cell substrate and the cell insulation layer;
before bonding the peripheral circuit substrate on the cell substrate, forming the second portion penetrating the peripheral circuit substrate and the peripheral circuit insulation layer; and
connecting the first portion and the second portion.

27. The method of claim 25,
wherein the through via includes:
a first portion penetrating the cell substrate and the cell insulation layer; and
a second portion penetrating the peripheral circuit substrate and the peripheral circuit insulation layer, and
wherein forming the through via comprises:
before bonding the peripheral circuit substrate on the cell substrate, forming the first portion penetrating the cell substrate and the cell insulation layer;
after bonding the peripheral circuit substrate on the cell substrate, forming a trench of the second portion penetrating the peripheral circuit substrate and the peripheral circuit insulation layer and exposing at least a part of the first portion; and
forming the second portion within the trench of the second portion.

28. The method of claim 25, wherein bonding the peripheral circuit substrate to the cell substrate comprises bonding the cell insulation layer and the peripheral circuit substrate.

29. The method of claim 25,
wherein forming the through via comprises:
after bonding the peripheral circuit substrate on the cell substrate,
forming a through via trench penetrating the cell substrate, the cell insulation layer, the peripheral circuit substrate, and the peripheral circuit insulation layer; and
forming a through via insulation layer surrounding the through via and the through via within the through via trench.
